SEQUENCE LISTING (13 sequences)

SEQ ID NO: 1 - DNA, 29 bp, Synthetic construct
  source 1..29: mol_type = other DNA
  modified_base 23: mod_base = OTHER; note = uracil
aatgatacggcgaccaccgagatctacac

SEQ ID NO: 2 - DNA, 29 bp, synthetic construct
  source 1..29: mol_type = other DNA
  modified_base 23: mod_base = i
aatgatacggcgaccaccgaganctacac

SEQ ID NO: 3 - DNA, 29 bp, Synthetic construct
  source 1..29: mol_type = other DNA
  modified_base 23: mod_base = OTHER; note = alkene-thymidine
aatgatacggcgaccaccgaganctacac

SEQ ID NO: 4 - DNA, 24 bp, Synthetic construct
  source 1..24: mol_type = other DNA
  modified_base 22: mod_base = OTHER; note = 8-oxoguanine
caagcagaagacggcatacganat

SEQ ID NO: 5 - DNA, 24 bp, Synthetic construct
  source 1..24: mol_type = other DNA
  modified_base 20: mod_base = OTHER; note = 8-oxoguanine
caagcagaagacggcatacnagat

SEQ ID NO: 6 - DNA, 24 bp, synthetic construct
  source 1..24: mol_type = other DNA
  modified_base 20: mod_base = OTHER; note = 8-oxoguanine
  modified_base 22: mod_base = OTHER; note = 8-oxoguanine
caagcagaagacggcatacnanat

SEQ ID NO: 7 - DNA, 29 bp, synthetic construct
  source 1..29: mol_type = other DNA
  modified_base 23: mod_base = OTHER; note = allyl-T
aatgatacggcgaccaccgaganctacac

SEQ ID NO: 8 - DNA, 35 bp, Synthetic construct
  source 1..35: mol_type = other DNA
gctggcacgtccgaacgcttcgttaatccgttgag

SEQ ID NO: 9 - DNA, 35 bp, Synthetic construct
  source 1..35: mol_type = other DNA
cgtcgtctgccatggcgcttcggtggatatgaact

SEQ ID NO: 10 - DNA, 35 bp, Synthetic construct
  source 1..35: mol_type = other DNA
acggccgctaatatcaacgcgtcgaatccgcaact

SEQ ID NO: 11 - DNA, 34 bp, Synthetic construct
  source 1..34: mol_type = other DNA
gccgcgttacgttagccggactattcgatgcagc

SEQ ID NO: 12 - DNA, 24 bp, Synthetic construct
  source 1..24: mol_type = other DNA
aggaggaggaggaggaggaggagg

SEQ ID NO: 13 - DNA, 24 bp, Synthetic construct
  source 1..24: mol_type = other DNA
cctcctcctcctcctcctcctcct

(19) United States
(12) Patent Application Publication
(10) Pub. No.: US 2024/0288765 A1
(43) Pub. Date: Aug. 29, 2024

(54) FLOW CELLS AND METHODS FOR MAKING THE SAME

(71) Applicant: ILLUMINA, INC., San Diego, CA (US)

(72) Inventors: Ravi Billa, Foster City, CA (US); Tara Bozorg-Grayeli, Woodside, CA (US); Arvin Emadi, Hayward, CA (US); Cassandra Renee Greene Chamoun, San Mateo, CA (US); Vanessa Montano-Machado, San Diego, CA (US); Roger Park, San Diego, CA (US)

(21) Appl. No.: 18/444,438

(22) Filed: Feb. 16, 2024

Related U.S. Application Data
(60) Provisional application No. 63/485,695, filed on Feb. 17, 2023.

(51) Int. Cl. G03F 7/00; C23C 14/18; C23C 14/24; C23C 14/58; G03F 7/30

(52) U.S. Cl. CPC G03F 7/0035; C23C 14/185; C23C 14/24; C23C 14/5873; G03F 7/0002; G03F 7/30

(57) ABSTRACT

In an example of a method for making a flow cell, a sacrificial layer is deposited over a substrate including depressions separated by interstitial regions. The sacrificial layer is dry etched from the depressions, and the sacrificial layer remains on the interstitial regions. A functionalized layer is deposited over the depressions and over the sacrificial layer. The sacrificial layer is removed from the interstitial regions, which also removes the functionalized layer that overlies the interstitial regions.

### CROSS-REFERENCE TO RELATED APPLICATIONS

This application claims the benefit of U.S. Provisional Application Ser. No. 63/485,695, filed Feb. 17, 2023, the content of which is incorporated by reference herein in its entirety.

### REFERENCE TO SEQUENCE LISTING

The Sequence Listing submitted herewith is hereby incorporated by reference in its entirety. The name of the file is ILI255B_IP-2505-US_Sequence_Listing.xml, the size of the file is 16,667 bytes, and the date of creation of the file is Feb. 12, 2024.

### BACKGROUND

Some available platforms for sequencing nucleic acids utilize a sequencing-by-synthesis approach. With this approach, a nascent strand is synthesized, and the addition of each monomer (e.g., nucleotide) to the growing strand is detected optically and/or electronically. Because a template strand directs synthesis of the nascent strand, one can infer the sequence of the template DNA from the series of nucleotide monomers that were added to the growing strand during the synthesis. In some examples, sequential paired-end sequencing may be used, where forward strands are sequenced and removed, and then reverse strands are constructed and sequenced. In other examples, simultaneous paired-end sequencing may be used, where forward strands and reverse strands are sequenced at the same time.

### SUMMARY

For some examples of sequential and simultaneous paired-end sequencing, one or more primer sets are attached to a polymeric hydrogel in a depression of a flow cell surface. Individual depressions are separated from one another by interstitial regions, and it is desirable for the interstitial regions to be free of both the polymeric hydrogel and the primer(s) for signal integrity. Several example methods are described herein to selectively apply the polymeric hydrogel and the primer set(s) in the depressions without applying them to the interstitial regions. These methods eliminate having to perform removal methods, such as polishing, which can lead to undesirable contamination (e.g., of the hydrogel and/or of the interstitial regions), surface alteration, and/or increasing the overall length of the manufacturing workflow.

### BRIEF DESCRIPTION OF THE DRAWINGS

Features of examples of the present disclosure will become apparent by reference to the following detailed description and drawings, in which like reference numerals correspond to similar, though perhaps not identical, components. For the sake of brevity, reference numerals or features having a previously described function may or may not be described in connection with other drawings in which they appear.

FIG. 1A is a top view of an example of a flow cell;

FIG. 1B is an enlarged, and partially cutaway view of an example of an architecture within a flow channel of the flow cell;

FIG. 1C is an enlarged, and partially cutaway view of another example of the architecture within the flow channel of the flow cell;

FIG. 2A is a schematic view of an example of first and second primer sets that are used in some examples of the flow cells disclosed herein;

FIG. 2B is a schematic view of another example of first and second primer sets that are used in other examples of the flow cells disclosed herein;

FIG. 2C is a schematic view of still another example of first and second primer sets that are used in still other examples of the flow cells disclosed herein;

FIG. 2D is a schematic view of yet another example of first and second primer sets that are used in yet other examples of the flow cells disclosed herein;

FIG. 3A through FIG. 3E are schematic views that together illustrate one example of the method disclosed herein, where FIG. 3A depicts the formation of a depression, FIG. 3B depicts the application of a sacrificial layer on the structure of FIG. 3A, FIG. 3C depicts the removal of the sacrificial layer from the depression, FIG. 3D depicts the application of a functionalized layer over the structure of FIG. 3C, and FIG. 3E depicts the removal of the sacrificial layer from interstitial regions;

FIG. 4A through FIG. 4D are schematic views that together illustrate another example method for the application of the sacrificial layer on the structure of FIG. 3A, where FIG. 4A depicts the application of a photoresist over the structure of FIG. 3A, FIG. 4B depicts the formation of insoluble and soluble portions of the photoresist and the removal of soluble portions of the photoresist from the structure of FIG. 4A, FIG. 4C depicts the application of the sacrificial layer over the structure of FIG. 4B, and FIG. 4D depicts the removal of the insoluble photoresist from the structure of FIG. 4C;

FIG. 5A through FIG. 5G are schematic views that together illustrate an example of another method disclosed herein, where FIG. 5A depicts a depression that is defined in a substrate, FIG. 5B depicts the application of a first sacrificial layer over interstitial regions of the structure depicted in FIG. 5A, FIG. 5C depicts the application of a second sacrificial layer over the first sacrificial layer and over a first portion of the depression, FIG. 5D depicts the application of a first functionalized layer over the structure of FIG. 5C, FIG. 5E depicts the removal of the second sacrificial layer and the first functionalized layer thereon from the structure of FIG. 5D, FIG. 5F depicts the application of a second functionalized layer over the first sacrificial layer and over a second portion of the depression, and FIG. 5G depicts the removal of the first sacrificial layer from the structure of FIG. 5F;

FIG. 6A through FIG. 6D are schematic views that together illustrate another example method for the application of the second sacrificial layer on the structure of FIG. 5B, where FIG. 6A depicts the application of a photoresist over the structure of FIG. 5B; FIG. 6B depicts the formation of insoluble and soluble portions of the photoresist and the removal of soluble portions of the photoresist, FIG. 6C depicts the application of a second sacrificial layer over the structure of FIG. 6B, and FIG. 6D depicts the removal of the insoluble photoresist from the structure of FIG. 6C;

FIG. 7A through FIG. 7F are schematic views that together illustrate an example of yet another method disclosed herein, where FIG. 7A depicts a depression that is defined in a substrate, FIG. 7B depicts the application of a sacrificial layer having a first thickness in a first portion of a depression and having a second thickness on interstitial regions, FIG. 7C depicts the application of a first functionalized layer over the structure of FIG. 7B, FIG. 7D depicts the removal of some of the sacrificial layer and the first functionalized layer thereon from the structure of FIG. 7C to expose a second portion of the depression and to form a reduced sacrificial layer, FIG. 7E depicts the application of a second functionalized layer over the second portion of the depression and over the reduced sacrificial layer, and FIG. 7F depicts the removal of the reduced sacrificial layer from the structure of FIG. 7E;

FIG. 8A through FIG. 8H are schematic views that together illustrate another example method for the application of the sacrificial layer on the structure of FIG. 7A, where FIG. 8A depicts the application of a first photoresist over the structure of FIG. 7A, FIG. 8B depicts the formation of insoluble and soluble portions of the first photoresist and the removal of soluble portions of the first photoresist from the structure of FIG. 8A, FIG. 8C depicts the application of a first sacrificial layer over the structure of FIG. 8B, FIG. 8D depicts the removal of the insoluble first photoresist and the sacrificial layer thereon from the structure of FIG. 8C, FIG. 8E depicts the application of a second photoresist over the structure of FIG. 8D, FIG. 8F depicts the formation of insoluble and soluble portions of the second photoresist and the removal of soluble portions of the second photoresist, FIG. 8G depicts the application of a second sacrificial layer over the structure of FIG. 8F, and FIG. 8H depicts the removal of the insoluble photoresist and the second sacrificial layer thereon from the structure of FIG. 8G;

FIG. 9A and FIG. 9B are, respectively, scanning electron microscopy (SEM) images of a top view of flow cell surface similar to that shown in FIG. 3E before and after an acetone lift-off; and

FIG. 10 is a confocal microscope image (reproduced in black and white) of a flow cell surface similar to that shown in FIG. 3E, where a silicon nitride sacrificial layer had been used to generate a functionalized layer in depressions.

### DETAILED DESCRIPTION

Examples of the flow cells disclosed herein may be used for sequencing, examples of which include sequential paired-end nucleic acid sequencing or simultaneous paired-end nucleic acid sequencing.

For sequential paired-end sequencing, a primer set is attached within a depression of a flow cell. The primers in the primer set include orthogonal cleaving (linearization) chemistry that enables forward strands to be generated, sequenced, and then removed, and then enables reverse strands to be generated sequenced and then removed. In these examples, orthogonal cleaving chemistry may be realized through different cleavage sites that are attached to the different primers in the set. Several example methods are described to generate these flow cells.

For simultaneous paired-end sequencing, different primer sets are attached to different regions within each depression of the flow cell. In these examples, the primer sets may be controlled so that the cleaving (linearization) chemistry is orthogonal in the different regions. In these examples, orthogonal cleaving chemistry may be realized through identical cleavage sites that are attached to different primers in the different sets, or through different cleavage sites that are attached to different primers in the different sets. This enables a cluster of forward strands to be generated in one region and a cluster of reverse strands to be generated in another region. In an example, the regions are directly adjacent to one another. In another example, any space between the regions is small enough that clustering can span the two regions. In any of these examples, the forward and reverse strands are spatially separate, which separates the fluorescent signals from both reads while allowing for simultaneous base calling of each read. Several example methods are described to generate these flow cells.

### Definitions

It is to be understood that terms used herein will take on their ordinary meaning in the relevant art unless specified otherwise. Several terms used herein and their meanings are set forth below.

The singular forms “a”, “an”, and “the” include plural referents unless the context clearly dictates otherwise.

The terms comprising, including, containing and various forms of these terms are synonymous with each other and are meant to be equally broad.

The terms top, bottom, lower, upper, on, etc. are used herein to describe the flow cell and/or the various components of the flow cell. It is to be understood that these directional terms are not meant to imply a specific orientation, but are used to designate relative orientation between components. The use of directional terms should not be interpreted to limit the examples disclosed herein to any specific orientation(s).

The terms first, second, etc. also are not meant to imply a specific orientation or order, but rather are used to distinguish one component from another.

The term “each,” when used in reference to a collection of items, is intended to identify an individual item in the collection, but does not necessarily refer to every item in the collection. Exceptions can occur if explicit disclosure or context clearly dictates otherwise.

It is to be understood that the ranges provided herein include the stated range and any value or sub-range within the stated range, as if such values or sub-ranges were explicitly recited. For example, a range of about 400 nm to about 1 μm (1000 nm), should be interpreted to include not only the explicitly recited limits of about 400 nm to about 1 μm, but also to include individual values, such as about 708 nm, about 945.5 nm, etc., and sub-ranges, such as from about 425 nm to about 825 nm, from about 550 nm to about 940 nm, etc. Furthermore, when “about” and/or “substantially” are/is utilized to describe a value, the term(s) are/is meant to encompass minor variations (up to +/−10%) from the stated value.

As used herein, the term “attached” refers to the state of two things being joined, fastened, adhered, connected or bound to each other, either directly or indirectly. For example, a nucleic acid can be attached to a functionalized polymer by a covalent or non-covalent bond. A covalent bond is characterized by the sharing of pairs of electrons between atoms. A non-covalent bond is a physical bond that does not involve the sharing of pairs of electrons and can include, for example, hydrogen bonds, ionic bonds, van der Waals forces, hydrophilic interactions and hydrophobic interactions.

As used herein, a “bonding region” refers to an area of a patterned structure that is to be bonded to another material, which may be, as examples, a lid, a substrate, etc., or combinations thereof (e.g., a substrate and a lid). The bond that is formed at the bonding region may be a chemical bond (as described above), or a mechanical bond (e.g., using a fastener, etc.).

A “patterned structure” refers to a single-layer or multi-layer substrate that includes surface chemistry in a pattern, e.g., in depressions. The surface chemistry may include a functionalized layer and primers (e.g., used for library template capture and amplification). In some examples, the substrate has been exposed to patterning techniques (e.g., etching, lithography, etc.) in order to generate the pattern for the surface chemistry. However, the term “patterned structure” is not intended to imply that such patterning techniques have to be used to generate the pattern. The patterned structure may be generated via any of the methods disclosed hereinbelow.

A “patterned resin” refers to any polymer that can have depressions defined therein. Specific examples of resins and techniques for patterning the resins will be described further hereinbelow.

The term “substrate” refers to a structure upon which various components of the flow cell (e.g., a polymeric hydrogel, primer(s), etc.) may be added. The substrate may be a wafer, a panel, a rectangular sheet, a die, or any other suitable configuration. The substrate may be inert to a chemistry that is used to modify the depressions or that is present in the depressions. For example, a substrate can be inert to chemistry used to form the polymeric hydrogel, to attach primer(s), etc. The substrate may be a single layer base support or a multi-layer structure including a base support and a layer (upon which surface chemistry is introduced) over the base support. As such, the term “base support” refers to either a single layer base support or a base support that forms a part of a multi-layer structure.

In some example methods that utilize ultraviolet (UV) light, the substrate is capable of transmitting UV light (e.g., light that is used to pattern a photoresist).

As used herein, the term “flow cell” is intended to mean a vessel having a flow channel where a reaction can be carried out, an inlet for delivering reagent(s) to the flow channel, and an outlet for removing reagent(s) from the flow channel. In some examples, the flow cell also enables the detection of the reaction that occurs in the flow cell. For example, the flow cell can include one or more transparent surfaces allowing for the optical detection of arrays, optically labeled molecules, or the like.

As used herein, a “flow channel” or “channel” may be an area defined between two bonded components, which can selectively receive a liquid sample. In some examples, the flow channel may be defined between a patterned resin of a substrate and a lid, and thus may be in fluid communication with one or more depressions defined in the patterned resin. In other examples, the flow channel may be defined between two substrates (each of which has sequencing chemistry thereon), and thus may be in fluid communication with the surface chemistry of the substrates.

As used herein, the term “depression” refers to a discrete concave feature in a substrate having a surface opening that is at least partially surrounded by interstitial region(s) of the substrate. Depressions can have any of a variety of shapes at their opening in a surface including, as examples, round, elliptical, square, polygonal, star shaped (with any number of vertices), etc. The cross-section of a depression taken orthogonally with the surface can be curved, square, polygonal, hyperbolic, conical, angular, etc. As examples, the depression can be a well or two interconnected wells. The depression may also have more complex architectures, such as ridges, step features, etc.

As used herein, the term “interstitial region” refers to an area, e.g., of a single layer or multi-layer substrate that separates depressions (concave regions). For example, an interstitial region can separate one depression of an array from another depression of the array. The two depressions that are separated from each other can be discrete, i.e., lacking physical contact with each other. In many examples, the interstitial region is continuous, whereas the depressions are discrete, for example, as is the case for a plurality of depressions defined in an otherwise continuous surface. In other examples, the interstitial regions and the depressions are discrete, for example, as is the case for a plurality of depressions in the shape of trenches, which are separated by respective interstitial regions. The separation provided by an interstitial region can be partial or full separation. Interstitial regions may have a surface material that differs from the surface material of the depressions. For example, depressions can have a functionalized polymer and one or more primer sets therein, and the interstitial regions can be free of polymer and/or primer set(s).

As used herein, the “primer” is defined as a single stranded nucleic acid sequence (e.g., single strand DNA or single strand RNA). Some primers, referred to herein as amplification primers, serve as a starting point for template amplification and cluster generation. Other primers, referred to herein as sequencing primers, serve as a starting point for DNA or RNA synthesis. The 5′ terminus of the primer may be modified to allow a coupling reaction with a functional group of a polymer. The primer length can be any number of bases long and can include a variety of non-natural nucleotides. In an example, the sequencing primer is a short strand, ranging from 10 to 60 bases, or from 20 to 40 bases.

As used herein, a “nucleotide” includes a nitrogen containing heterocyclic base, a sugar, and one or more phosphate groups. Nucleotides are monomeric units of a nucleic acid sequence. In RNA, the sugar is a ribose, and in DNA, the sugar is a deoxyribose, i.e. a sugar lacking a hydroxyl group that is present at the 2′ position in ribose. The nitrogen containing heterocyclic base (i.e., nucleobase) can be a purine base or a pyrimidine base. Purine bases include adenine (A) and guanine (G), and modified derivatives or analogs thereof. Pyrimidine bases include cytosine (C), thymine (T), and uracil (U), and modified derivatives or analogs thereof. The C-1 atom of deoxyribose is bonded to the N-1 atom of a pyrimidine or to the N-9 atom of a purine. A nucleic acid analog may have any of the phosphate backbone, the sugar, or the nucleobase altered. Examples of nucleic acid analogs include, for example, universal bases or phosphate-sugar backbone analogs, such as peptide nucleic acid (PNA).

The term “depositing,” as used herein, refers to any suitable application technique, which may be manual or automated, and, in some instances, results in modification of surface properties. Generally, depositing may be performed using vapor deposition techniques, coating techniques, grafting techniques, or the like. Some specific examples include chemical vapor deposition (CVD), spray coating (e.g., ultrasonic spray coating), spin coating, dunk or dip coating, doctor blade coating, puddle dispensing, flow through coating, aerosol printing, screen printing, microcontact printing, inkjet printing, or the like.

The term “orthogonal,” when used to describe cleaving (linearization) chemistry, means that the reagent(s) used to cleave the cleavage site of one primer in a set are not capable of cleaving the cleavage site of another primer in the same set or a different set, and vice versa. Additionally, “orthogonal” sacrificial layers are susceptible to different removal chemistries. In other words, the etch reagent used to remove one sacrificial layer will not (completely) remove another sacrificial layer due to the other sacrificial layer i) being inert to the etch reagent or ii) having a much lower etch rate when exposed to the etch reagent for another sacrificial layer.

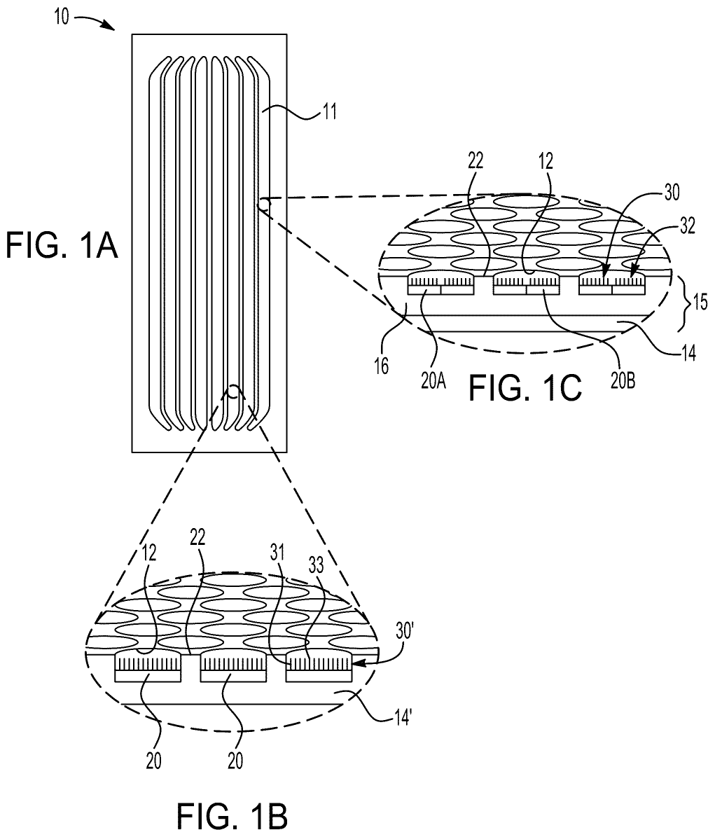

In some examples, the term “over” may mean that one component or material is positioned directly on another component or material. When one is directly on another, the two are in contact with each other. For example, in the multi-layer substrate 15 shown in FIG. 1C, the layer 16 is applied over the base support 14 so that the layer 16 is directly on and in contact with the base support 14.

In other examples, the term “over” may mean that one component or material is positioned indirectly on another component or material. By indirectly on, it is meant that a gap or an additional component or material may be positioned between the two components or materials. For example, in FIG. 1C, the functionalized layers 20A, 20B are positioned over the base support 14 of a multi-layer substrate 15, such that the two are in indirect contact. The layer 16 is positioned therebetween.

As used herein, a “negative photoresist” refers to a light sensitive material in which a portion that is exposed to light of particular wavelength(s) becomes insoluble in a developer. In an example of the methods disclosed herein, the insoluble negative photoresist has less than 5% solubility in the developer. With the negative photoresist, the light exposure changes the chemical structure so that the exposed portions of the material becomes less soluble (than non-exposed portions) in the developer. While not soluble in the developer, the insoluble negative photoresist may be at least 99% soluble in a remover that is different from the developer. The remover may be a solvent or solvent mixture used, e.g., in a lift-off process.

In contrast to the insoluble negative photoresist, any portion of the negative photoresist that is not exposed to light is at least 95% soluble in the developer. In some examples, the portion of the negative photoresist not exposed to light is at least 98%, e.g., 99%, 99.5%, 100%, soluble in the developer.

As used herein, a “positive photoresist” refers to a light sensitive material in which a portion that is exposed to light of particular wavelength(s) becomes soluble to a developer. In these examples, any portion of the positive photoresist exposed to light is at least 95% soluble in the developer. In some examples, the portion of the positive photoresist exposed to light is at least 98%, e.g., 99%, 99.5%, 100%, soluble in the developer. With the positive photoresist, the light exposure changes the chemical structure so that the exposed portions of the material become more soluble (than non-exposed portions) in the developer.

In contrast to the soluble positive photoresist, any portion of the positive photoresist not exposed to light is insoluble (less than 5% soluble) in the developer. While not soluble in the developer, the insoluble positive photoresist may be at least 99% soluble in a remover that is different from the developer. In some examples, the insoluble positive photoresist is at least 98%, e.g., 99%, 99.5%, 100%, soluble in the remover. The remover may be a solvent or solvent mixture used in a lift-off process.

The term “transparent” refers to a material, e.g., in the form of a single layer or multi-layer substrate, that is capable of transmitting a particular wavelength or range of wavelengths. For example, the material may be transparent to wavelength(s) that are used to chemically change a positive or negative photoresist. Transparency may be quantified using transmittance, i.e., the ratio of light energy falling on a body to that transmitted through the body. The transmittance of a substrate will depend upon the thickness of the substrate, the wavelength of light, and the dosage of the light to which it is exposed. In the examples disclosed herein, the transmittance of the transparent material may range from 0.25 (25%) to 1 (100%). The material of the substrate may be a pure material, a material with some impurities, or a mixture of materials, as long as the resulting base support or substrate is capable of the desired transmittance. Additionally, depending upon the transmittance of the substrate, the time for light exposure and/or the output power of the light source may be increased or decreased to deliver a suitable dose of light energy through the substrate to achieve the desired effect (e.g., generating a soluble or insoluble photoresist).

An “acrylamide monomer” is a monomer with the structure

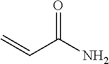

or a monomer including an acrylamide group with that structure. Examples of the monomer including an acrylamide group include azido acetamido pentyl acrylamide:

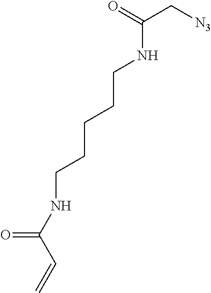 [SMILES: C=CC(=O)NCCCCCNC(=O)CN=[N+]=[N-]]

### and N-isopropylacrylamide:

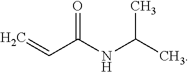

Other acrylamide monomers may be used.

An aldehyde, as used herein, is an organic compound containing a functional group with the structure —CHO, which includes a carbonyl center (i.e., a carbon double-bonded to oxygen) with the carbon atom also bonded to hydrogen and an R group, such as an alkyl or other side chain. The general structure of an aldehyde is:

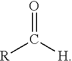

As used herein, “alkyl” refers to a straight or branched hydrocarbon chain that is fully saturated (i.e., contains no double or triple bonds). The alkyl group may have 1 to 20 carbon atoms. Example alkyl groups include methyl, ethyl, propyl, isopropyl, butyl, isobutyl, tertiary butyl, pentyl, hexyl, and the like. As an example, the designation “C1-4 alkyl” indicates that there are one to four carbon atoms in the alkyl chain, i.e., the alkyl chain is selected from the group consisting of methyl, ethyl, propyl, iso-propyl, n-butyl, isobutyl, sec-butyl, and t-butyl.

As used herein, “alkenyl” refers to a straight or branched hydrocarbon chain containing one or more double bonds. The alkenyl group may have 2 to 20 carbon atoms. Example alkenyl groups include ethenyl, propenyl, butenyl, pentenyl, hexenyl, and the like.

As used herein, “alkyne” or “alkynyl” refers to a straight or branched hydrocarbon chain containing one or more triple bonds. The alkynyl group may have 2 to 20 carbon atoms.

As used herein, “aryl” refers to an aromatic ring or ring system (i.e., two or more fused rings that share two adjacent carbon atoms) containing only carbon in the ring backbone. When the aryl is a ring system, every ring in the system is aromatic. The aryl group may have 6 to 18 carbon atoms. Examples of aryl groups include phenyl, naphthyl, azulenyl, and anthracenyl.

An “amine” or “amino” functional group refers to an —NRₐR_{b} group, where Rₐ and R_{b} are each independently selected from hydrogen

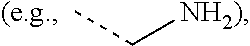

C1-6 alkyl, C2-6 alkenyl, C2-6 alkynyl, C3-7 carbocyclyl, C6-10 aryl, 5-10 membered heteroaryl, and 5-10 membered heterocyclyl, as defined herein.

An “azide” or “azido” functional group refers to —N₃.

As used herein, “carbocycle” means a non-aromatic cyclic ring or ring system containing only carbon atoms in the ring system backbone. When the carbocycleis a ring system, two or more rings may be joined together in a fused, bridged or spiro-connected fashion. Carbocycles may have any degree of saturation, provided that at least one ring in a ring system is not aromatic. Thus, carbocycles include cycloalkyls, cycloalkenyls, and cycloalkynyls. The carbocycle group may have 3 to 20 carbon atoms. Examples of carbocyclyl rings include cyclopropyl, cyclobutyl, cyclopentyl, cyclohexyl, cyclohexenyl, 2,3-dihydro-indene, bicyclo[2.2.2]octanyl, adamantyl, and spiro[4.4]nonanyl.

As used herein, the term “carboxylic acid” or “carboxyl” as used herein refers to —COOH.

As used herein, “cycloalkylene” means a fully saturated carbocyclyl ring or ring system that is attached to the rest of the molecule via two points of attachment.

As used herein, “cycloalkenyl” or “cycloalkene” means a carbocyclyl ring or ring system having at least one double bond, wherein no ring in the ring system is aromatic. Examples include cyclohexenyl or cyclohexene and norbornenyl or norbornene. Also as used herein, “heterocycloalkenyl” or “heterocycloalkene” means a carbocycle ring or ring system with at least one heteroatom in ring backbone, having at least one double bond, wherein no ring in the ring system is aromatic.

As used herein, “cycloalkynyl” or “cycloalkyne” means a carbocycle ring or ring system having at least one triple bond, wherein no ring in the ring system is aromatic. An example is cyclooctyne. Another example is bicyclononyne. Also as used herein, “heterocycloalkynyl” or “heterocycloalkyne” means a carbocycle ring or ring system with at least one heteroatom in ring backbone, having at least one triple bond, wherein no ring in the ring system is aromatic.

The term “epoxy” (also referred to as a glycidyl or oxirane group) as used herein refers to

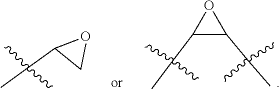

As used herein, “heteroaryl” refers to an aromatic ring or ring system (i.e., two or more fused rings that share two adjacent atoms) that contain(s) one or more heteroatoms, that is, an element other than carbon, including but not limited to, nitrogen, oxygen and sulfur, in the ring backbone. When the heteroaryl is a ring system, every ring in the system is aromatic. The heteroaryl group may have 5-18 ring members.

As used herein, “heterocycle” means a non-aromatic cyclic ring or ring system containing at least one heteroatom in the ring backbone. Heterocycles may be joined together in a fused, bridged or spiro-connected fashion. Heterocycles may have any degree of saturation provided that at least one ring in the ring system is not aromatic. In the ring system, the heteroatom(s) may be present in either a non-aromatic or aromatic ring. The heterocycle group may have 3 to 20 ring members (i.e., the number of atoms making up the ring backbone, including carbon atoms and heteroatoms). In some examples, the heteroatom(s) is/are O, N, or S.

The term “hydrazine” or “hydrazinyl” as used herein refers to a —NHNH₂ group.

As used herein, the term “hydrazone” or “hydrazonyl” as used herein refers to a

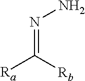

group in which Rₐ and R_{b} are each independently selected from hydrogen, C1-6 alkyl, C2-6 alkenyl, C2-6 alkynyl, C3-7 carbocyclyl, C6-10 aryl, 5-10 membered heteroaryl, and 5-10 membered heterocyclyl, as defined herein.

As used herein, “hydroxy” or “hydroxyl” refers to an —OH group.

“Nitrile oxide,” as used herein, means a “RₐC≡N⁺O⁻” group in which Rₐ is defined herein. Examples of preparing nitrile oxide include in situ generation from aldoximes by treatment with chloramide-T or through action of base on imidoyl chlorides [RC(Cl)═NOH] or from the reaction between hydroxylamine and an aldehyde.

“Nitrone,” as used herein, means a

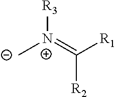

group in which R₁, R₂, and R₃ may be any of the Rₐ and R_{b} groups defined herein.

A “thiol” functional group refers to —SH.

As used herein, the terms “tetrazine” and “tetrazinyl” refer to a six-membered heteroaryl group comprising four nitrogen atoms. Tetrazine can be optionally substituted.

“Tetrazole,” as used herein, refers to a five-membered heterocyclic group including four nitrogen atoms. Tetrazole can be optionally substituted.

As used herein, the term “polyhedral oligomeric silsesquioxane” refers to a chemical composition that is a hybrid intermediate (e.g., RSiO_{1.5}) between that of silica (SiO₂) and silicone (R₂SiO). An example of polyhedral oligomeric silsesquioxane may be that described in Kehagias et al., Microelectronic Engineering 86 (2009), pp. 776-778, which is incorporated by reference in its entirety. In an example, the composition is an organosilicon compound with the chemical formula [RSiO_{3/2}]ₙ, where the R groups can be the same or different. Example R groups for polyhedral oligomeric silsesquioxane include epoxy, azide/azido, a thiol, a poly(ethylene glycol), a norbornene, a tetrazine, acrylates, and/or methacrylates, or further, for example, alkyl, aryl, alkoxy, and/or haloalkyl groups.

### Flow Cells

An example of a flow cell for sequential paired-end sequencing generally comprises a patterned structure including a substrate, a functionalized layer over at least a portion of the substrate; and a primer set including two different primers attached to the functionalized layer.

An example of a flow cell for simultaneous paired-end sequencing generally comprises a patterned structure, which includes a substrate; two functionalized layers over at least a portion of the substrate; and different primer sets attached to the two functionalized layers.

One example of the flow cell 10 is shown in FIG. 1A from a top view. While not shown in the figure, the flow cell 10 may include two patterned structures bonded together or one patterned structure bonded to a lid. These examples may be referred to herein as enclosed flow cells. In other examples, the flow cell 10 is an open-wafer flow cell that includes a single patterned structure that is open to the surrounding environment.

Between the two patterned structures or the one patterned structure and the lid of an enclosed flow cell 10 is a flow channel 11. The two patterned structures or the one patterned structure and the lid may be bonded together via a spacer layer (not shown). Thus, in the enclosed flow cell examples, each flow channel 11 is defined by the patterned structure, the spacer layer, and either the lid or the second patterned structure.

In the open-wafer flow cell, the patterned structure may include a lane that defines a flow channel 11. Alternatively, the open-wafer flow cell may be a flat surface to which liquid reagents can be applied, and thus may not have a defined flow channel 11.

The example shown in FIG. 1A includes eight flow channels 11. While eight flow channels 11 are shown in the figure, it is to be understood that any number of flow channels 11 may be included in the flow cell 10 (e.g., a single flow channel 11, four flow channels 11, etc.). Each flow channel 11 may be isolated from each other flow channel 11 so that fluid introduced into one flow channel 11 does not flow into adjacent flow channel(s) 11. Some examples of the fluids introduced into the flow channel 11 may introduce reaction components (e.g., DNA sample, polymerases, sequencing primers, nucleotides, etc.), washing solutions, deblocking agents, etc.

Each flow channel 11 is in fluid communication with an inlet and an outlet (not shown). The inlet and outlet of each flow channel 11 may be positioned at opposed ends of the flow cell 10. The inlets and outlets of the respective flow channels 11 may alternatively be positioned anywhere along the length and width of the flow channel 11 that enables desirable fluid flow.

The inlet allows fluids to be introduced into the flow channel 11, and the outlet allows fluid to be extracted from the flow channel 11. Each of the inlets and outlets is fluidly connected to a fluidic control system (including, e.g., reservoirs, pumps, valves, waste containers, and the like) which controls fluid introduction and expulsion.

The flow channel 11 may have any desirable shape. In an example, the flow channel 11 has a substantially rectangular configuration with curved ends (as shown in FIG. 1A). The length of the flow channel 11 depends, in part, upon the size of the substrate (e.g., 14′ or 15, see FIG. 1B and FIG. 1C) used to form the patterned structure. The width of the flow channel 11 depends, in part, upon the size of the substrate 14′ or 15 used to form the patterned structure, the desired number of flow channels 11, the desired space between adjacent channels 11, and the desired space at a perimeter of the patterned structure. The spaces between channels 11 and at the perimeter may be sufficient for attachment to a lid (not shown) or another patterned structure (also not shown).

The depth of the flow channel 11 (e.g., that is partially defined by layer 16 or the single layer substrate 14′) can be as small as a monolayer thick when microcontact, aerosol, or inkjet printing is used to deposit a separate (spacer) material that defines the flow channel 11 walls. For other examples, the depth of the flow channel 11 can be about 1 μm, about 10 μm, about 50 μm, about 100 μm, or more. In an example, the depth may range from about 10 μm to about 100 μm. In another example, the depth may range from about 10 μm to about 30 μm. In still another example, the depth is about 5 μm or less. It is to be understood that the depth of the flow channel 11 may be greater than, less than or between the values specified above.

The spacer layer used to attach the patterned structure and the lid or the second patterned structure may be any material that will seal portions of the patterned structure and the lid or the second patterned structure. As examples, the spacer layer may be an adhesive, a radiation-absorbing material that aids in bonding, or the like. In some examples, the spacer layer is the radiation-absorbing material, e.g., KAPTON® black (DuPont de Nemours, Inc.).

The patterned structure and the lid or the second patterned structure may be bonded using any suitable technique, such as laser bonding, diffusion bonding, anodic bonding, eutectic bonding, plasma activation bonding, glass frit bonding, or others methods known in the art.

When used, the lid may be any material that is transparent to the excitation light that is directed toward the flow cell 10. In optical detection systems, the lid may also be transparent to the emissions generated from reaction(s) taking place in the flow cell 10. As examples, the lid may include glass (e.g., borosilicate, fused silica, etc.) or a transparent polymer. A commercially available example of a suitable borosilicate glass is D 263®, available from Schott North America Inc. Commercially available examples of suitable polymer materials, namely cycloolefin polymers, are the ZEONOR® products available from Zeon Chemicals L.P. In some instances, the lid is shaped to form the top of the flow cell 10, and in other instances, the lid is shaped to form both the top of the flow cell as well as sidewalls the flow channel 11.

The patterned structure includes a bonding region where it can be sealed to the lid or to the second patterned structure. The bonding region may be located at the perimeter of each flow channel 11 and at the perimeter of the flow cell 10.

The flow channel 11 is at least partially defined by at least one patterned structure. The patterned structure may include a substrate, such as a single layer base support 14′ (as shown in FIG. 1B), or a multi-layer substrate 15 including a base support 14 and a layer 16 on the base support 14 (as shown in FIG. 1C). As such, the flow channel 11 may be defined in the layer 16 (of the multi-layer substrate 15), or in the single layer base support 14′.

Examples of suitable single layer base supports 14′ (or base supports 14, when a multi-layer substrate 15 is used) include epoxy siloxane, glass, modified or functionalized glass, plastics (including acrylics, polystyrene and copolymers of styrene and other materials, polypropylene, polyethylene, polybutylene, polyurethanes, polytetrafluoroethylene (such as TEFLON® from Chemours), cyclic olefins/cyclo-olefin polymers (COP) (such as ZEONOR® from Zeon), polyimides, etc.), nylon (polyamides), ceramics/ceramic oxides, silica, fused silica, or silica-based materials, aluminum silicate, silicon and modified silicon (e.g., boron doped p+ silicon), silicon nitride (Si₃N₄), silicon oxide (SiO₂), tantalum pentoxide (Ta₂O₅) or other tantalum oxide(s) (TaOₓ), hafnium oxide (HfO₂), carbon, metals, inorganic glasses, resins, or the like.

In an example, the single layer base support 14′ (or the base support 14, when used as part of the multi-layer structure 15) may be a circular sheet, a panel, a wafer, a die etc. having a diameter ranging from about 2 mm to about 300 mm, e.g., from about 200 mm to about 300 mm, or may be a rectangular sheet, panel, wafer, die etc. having its largest dimension up to about 10 feet (˜3 meters). For example, a die may have a width ranging from about 0.1 mm to about 10 mm. While example dimensions have been provided, it is to be understood that a base support 14, 14′ with any suitable dimensions may be used.

As explained hereinabove, examples of the multi-layer structure 15 (when used) include the base support 14 (e.g., glass, silicon, tantalum pentoxide, or any of the other single layer base support 14′ materials) and at least one other layer 16 thereon, as shown in FIG. 1C.

In some of these examples, an inorganic oxide may be selectively applied to the base support 14 of the multi-layer structure 15 via vapor deposition, aerosol printing, or inkjet printing to form the layer 16. Examples of suitable inorganic oxides include tantalum oxide (e.g., Ta₂O₅), aluminum oxide (e.g., Al₂O₃), silicon oxide (e.g., SiO₂), hafnium oxide (e.g., HfO₂), etc. Other examples of the multi-layer structure 15 include the base support 14 and a patterned resin as the other layer 16. Some examples of suitable resins for the layer 16 include a polyhedral oligomeric silsesquioxane resin (e.g., commercially available under the tradename POSS® from Hybrid Plastics), a non-polyhedral oligomeric silsesquioxane epoxy resin, a poly(ethylene glycol) resin, a polyether resin (e.g., ring opened epoxies), an acrylic resin, an acrylate resin, a methacrylate resin, an amorphous fluoropolymer resin (e.g., CYTOP® from Bellex), and combinations thereof. It is to be understood that any resin material that can be selectively deposited, or deposited (on the base support 14) and patterned to form depressions 12 and interstitial regions 22, may be used for the patterned resin of the layer 16 for the multi-layer substrate 15.

Suitable deposition techniques for the layer 16 include chemical vapor deposition, dip coating, dunk coating, spin coating, spray coating, puddle dispensing, ultrasonic spray coating, doctor blade coating, aerosol printing, screen printing, microcontact printing, etc. Suitable patterning techniques for the layer 16 include photolithography, nanoimprint lithography (NIL), stamping techniques, embossing techniques, molding techniques, microetching techniques, etc. The deposition and patterning techniques that are used may depend, in part, upon the material used for the base support 14 and for the material used for the layer 16.

As shown in FIG. 1B and FIG. 1C, the base support 14′ or the layer 16 may have depressions 12 defined therein. Thus, the depressions 12 are in fluid communication with the flow channel 11.

Many different layouts of the depressions 12 may be envisaged, including regular, repeating, and non-regular patterns. In an example, the depressions 12 are disposed in a hexagonal grid for close packing and improved density. Other layouts may include, for example, rectilinear (rectangular) layouts, triangular layouts, and so forth. In some examples, the layout or pattern can be an x-y format in rows and columns. In some other examples, the layout or pattern can be a repeating arrangement of the depressions 12 and the interstitial regions 22. In still other examples, the layout or pattern can be a random arrangement of the depressions 12 and the interstitial regions 22.

The layout or pattern may be characterized with respect to the density (number) of the depressions 12 in a defined area. For example, the depressions 12 may be present at a density of approximately 2 million per mm². The density may be tuned to different densities including, for example, a density of about 100 per mm², about 1,000 per mm², about 0.1 million per mm², about 1 million per mm², about 2 million per mm², about 5 million per mm², about 10 million per mm², about 50 million per mm², or more, or less. It is to be further understood that the density can be between one of the lower values and one of the upper values selected from the ranges above, or that other densities (outside of the given ranges) may be used. As examples, a high density array may be characterized as having the depressions 12 separated by less than about 100 nm, a medium density array may be characterized as having the depressions 12 separated by about 400 nm to about 1 μm, and a low density array may be characterized as having the depressions 12 separated by greater than about 1 μm.

The layout or pattern of the depressions 12 may also or alternatively be characterized in terms of the average pitch, or the spacing from the center of one depression 12 to the center of an adjacent depression 12, or from the right edge of one depression 12 to the left edge of an adjacent depression 12 (edge-to-edge spacing). The pattern can be regular, such that the coefficient of variation around the average pitch is small, or the pattern can be non-regular in which case the coefficient of variation can be relatively large. In either case, the average pitch can be, for example, about 50 nm, about 0.1 μm, about 0.5 μm, about 1 μm, about 5 μm, about 10 μm, about 100 μm, or more or less. The average pitch for a particular pattern of depressions 12 can be between one of the lower values and one of the upper values selected from the ranges above. In an example, the depressions 12 have a pitch (center-to-center spacing) of about 1.5 μm. While example average pitch values have been provided, it is to be understood that other average pitch values may be used.

The size of each depression 12 may be characterized by its volume, opening area, depth, and/or diameter or length and width. For example, the volume can range from about 1×10⁻³ μm³ to about 100 μm³, e.g., about 1×10⁻² μm³, about 0.1 μm³, about 1 μm³, about 10 μm³, or more, or less. For another example, the opening area can range from about 1×10⁻³ μm² to about 100 μm², e.g., about 1×10−2 μm², about 0.1 μm², about 1 μm², at least about 10 μm², or more, or less. For still another example, the depth can range from about 0.1 μm to about 100 μm, e.g., about 0.5 μm, about 1 μm, about 10 μm, or more, or less. For another example, the depth can range from about 0.1 μm to about 100 μm, e.g., about 0.5 μm, about 1 μm, about 10 μm, or more, or less. For yet another example, the diameter or each of the length and the width can range from about 0.1 μm to about 100 μm, e.g., about 0.5 μm, about 1 μm, about 10 μm, or more, or less.

The depressions 12 used for sequential paired-end sequencing include a single functionalized layer 20 (as shown in FIG. 1B). The functionalized layer 20 represents an area that may have a primer set 30′ (including primers 31, 33) attached thereto. The depressions 12 used for simultaneous paired-end sequencing include two functionalized layers 20A, 20B (as shown in FIG. 1C). The functionalized layers 20A, 20B represent different areas that have respective primer sets 30, 32 attached thereto.

In some of the examples disclosed herein, the functionalized layers 20A, 20B (when used) are chemically the same, and any of the techniques disclosed hereinbelow may be used to sequentially immobilize the primer sets 30, 32 to the desired layer 20A, 20B. In other examples disclosed herein, the functionalized layers 20A, 20B are chemically different (e.g., the layers 20A, 20B include different functional groups for respective primer set 30, 32 attachment), and any of the techniques disclosed herein may be used to immobilize the primer sets 30, 32 to the respective layers 20A, 20B. In other examples disclosed herein, the materials applied to form the functionalized layers 20A, 20B may have the respective primer sets 30, 32 pre-grafted thereto, and thus the immobilization chemistries of the functionalized layers 20A, 20B may be the same or different.

In some examples, the functionalized layer 20 (or layers 20A, 20B, when used) may be any gel material that can swell when liquid is taken up and can contract when liquid is removed, e.g., by drying. In an example, the gel material is a polymeric hydrogel. In an example, the polymeric hydrogel includes an acrylamide copolymer, such as poly(N-(5-azidoacetamidylpentyl)acrylamide-co-acrylamide, PAZAM. PAZAM and some other forms of the acrylamide copolymer are represented by the following structure (I):

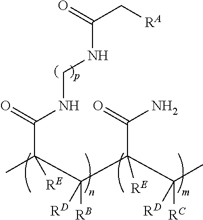

wherein:
R^{A} is selected from the group consisting of azido, optionally substituted amino, optionally substituted alkenyl, optionally substituted alkyne, halogen, optionally substituted hydrazone, optionally substituted hydrazine, carboxyl, hydroxy, optionally substituted tetrazole, optionally substituted tetrazine, nitrile oxide, nitrone, sulfate, and thiol;
R^{B} is H or optionally substituted alkyl;
R^{C}, R^{D}, and R^{E} are each independently selected from the group consisting of H and optionally substituted alkyl;
each of the —(CH₂)ₚ— can be optionally substituted;
p is an integer in the range of 1 to 50;
n is an integer in the range of 1 to 50,000; and
m is an integer in the range of 1 to 100,000.

One of ordinary skill in the art will recognize that the arrangement of the recurring “n” and “m” features in structure (I) are representative, and the monomeric subunits may be present in any order in the polymer structure (e.g., random, block, patterned, or a combination thereof).

The molecular weight of PAZAM and other forms of the acrylamide copolymer may range from about 5 kDa to about 1500 kDa or from about 10 kDa to about 1000 kDa, or may be, in a specific example, about 312 kDa.

In some examples, PAZAM and other forms of the acrylamide copolymer are linear polymers. In some other examples, PAZAM and other forms of the acrylamide copolymer are lightly cross-linked polymers.

In other examples, the gel material may be a variation of the structure (I). In one example, the acrylamide unit may be replaced with N,N-dimethylacrylamide

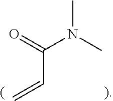

In this example, the acrylamide unit in structure (I) may be replaced with

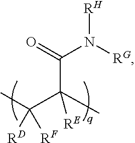

where R^{D}, R^{E}, and R^{F} are each H or a C1-C6 alkyl, and R^{G} and R^{H} are each a C1-C6 alkyl (instead of H as is the case with the acrylamide). In this example, q may be an integer in the range of 1 to 100,000. In another example, the N,N-dimethylacrylamide may be used in addition to the acrylamide unit. In this example, structure (I) may include

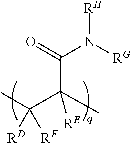

in addition to the recurring “n” and “m” features, where R^{D}, R^{E}, and R^{F} are each H or a C1-C6 alkyl, and R^{G} and R^{H} are each a C1-C6 alkyl. In this example, q may be an integer in the range of 1 to 100,000.

As another example of the polymeric hydrogel, the recurring “n” feature in structure (I) may be replaced with a monomer including a heterocyclic azido group having structure (II):

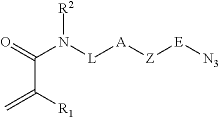

wherein R¹ is H or a C1-C6 alkyl; R₂ is H or a C1-C6 alkyl; L is a linker including a linear chain with 2 to 20 atoms selected from the group consisting of carbon, oxygen, and nitrogen and 10 optional substituents on the carbon and any nitrogen atoms in the chain; E is a linear chain including 1 to 4 atoms selected from the group consisting of carbon, oxygen and nitrogen, and optional substituents on the carbon and any nitrogen atoms in the chain; A is an N substituted amide with an H or a C1-C4 alkyl attached to the N; and Z is a nitrogen containing heterocycle. Examples of Z include 5 to 10 carbon-containing ring members present as a single cyclic structure or a fused structure. Some specific examples of Z include pyrrolidinyl, pyridinyl, or pyrimidinyl.

As still another example, the gel material may include a recurring unit of each of structure (III) and (IV):

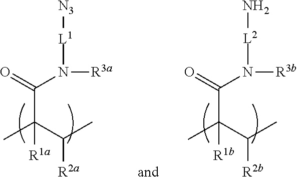

wherein each of R^{1a}, R^{2a}, R^{1b} and R^{2b} is independently selected from hydrogen, an optionally substituted alkyl or optionally substituted phenyl; each of R^{3a} and R^{3b} is independently selected from hydrogen, an optionally substituted alkyl, an optionally substituted phenyl, or an optionally substituted C7-C14 aralkyl; and each L¹ and L² is independently selected from an optionally substituted alkylene linker or an optionally substituted heteroalkylene linker.

It is to be understood that other molecules may be used to form the functionalized layers 20 or 20A, 20B as long as they are functionalized to graft oligonucleotide primer sets 30′ or 30, 32 thereto. Some examples of suitable functionalized layer materials include functionalized silanes, such as norbornene silane, azido silane, alkyne functionalized silane, amine functionalized silane, maleimide silane, or any other silane having functional groups that can attach the desired primer set. Other examples of suitable functionalized layer materials include those having a colloidal structure, such as agarose; or a polymer mesh structure, such as gelatin; or a cross-linked polymer structure, such as polyacrylamide polymers and copolymers, silane free acrylamide (SFA), or an azidolyzed version of SFA. Examples of suitable polyacrylamide polymers may be synthesized from acrylamide and an acrylic acid or an acrylic acid containing a vinyl group, or from monomers that form [2+2] photo-cycloaddition reactions. Still other examples of suitable polymeric hydrogels include mixed copolymers of acrylamides and acrylates. A variety of polymer architectures containing acrylic monomers (e.g., acrylamides, acrylates etc.) may be utilized in the examples disclosed herein, such as branched polymers, including star polymers, star-shaped or star-block polymers, dendrimers, and the like. For example, the monomers (e.g., acrylamide, acrylamide containing the catalyst, etc.) may be incorporated, either randomly or in block, into the branches (arms) of a star-shaped polymer.

The gel material of the functionalized layers 20 or 20A, 20B may be formed using any suitable copolymerization process. The gel material may also be deposited using any of the deposition methods disclosed herein.

The attachment of the functionalized layers 20 or 20A, 20B to the underlying base support 14′ (or to the layer 16 of the multi-layer substrate 15) may be through covalent bonding. In some example methods described hereinbelow, the underlying base support 14′ (or layer 16 of the multi-layer substrate 15) may first be activated, e.g., through silanization or plasma ashing, for attachment of the functionalized layer 20 or 20A, 20B. Covalent linking may be helpful for maintaining the primer set in the desired regions throughout the lifetime of the flow cell 10 during a variety of uses.

As explained previously, the depressions 12 also include the primer set 30′ attached to the functionalized layer 20, or the primer sets 30, 32 attached to respective functionalized layers 20A, 20B.

The primer set 30′ includes two different primers 31, 33 that are used in sequential paired end sequencing. As examples, the primer set 30′ may include P5 and P7 primers, P15 and P7 primers, or any combination of the PA primers, the PB primers, the PC primers, and the PD primers set forth herein. As examples, the primer set 30′ may include any two PA, PB, PC, and PD primers, or any combination of one PA primer and one PB, PC, or PD primer, or any combination of one PB primer and one PC or PD primer, or any combination of one PC primer and one PD primer.

Examples of P5 and P7 primers are used on the surface of commercial flow cells sold by Illumina Inc. for sequencing, for example, on HISEQ™, HISEQX™, MISEQ™, MISEQDX™, MINISEQ™, NEXTSEQ™, NEXTSEQDX™, NOVASEQ™, ISEQ™, GENOME ANALYZER™, and other instrument platforms. The P5 primer may be any of the following:

P5 #1: 5′→3′
(SEQ. ID. NO. 1)
AATGATACGGCGACCACCGAGAUCTACAC;
P5 #2: 5′→3′
(SEQ. ID. NO. 2)
AATGATACGGCGACCACCGAGAnCTACAC

where “n” is inosine in SEQ. ID. NO. 2; or

P5 #2: 5′→3′
(SEQ. ID. NO. 3)
AATGATACGGCGACCACCGAGAnCTACAC

where “n” is alkene-thymidine (i.e., alkene-dT) in SEQ. ID. NO. 3.

The P7 primer may be any of the following:

P7 #1: 5′→3′
(SEQ. ID. NO. 4)
CAAGCAGAAGACGGCATACGAnAT;
P7 #2: 5′→3′
(SEQ. ID. NO. 5)
CAAGCAGAAGACGGCATACnAGAT;
or
7 #3: 5′→3′
(SEQ. ID. NO. 6)
CAAGCAGAAGACGGCATACnAnAT

where “n” is 8-oxoguanine in each of SEQ. ID. NOS. 4-6.

The P15 primer is:

P15: 5′→3′
(SEQ. ID. NO. 7)
AATGATACGGCGACCACCGAGAnCTACAC

where “n” is allyl-T (i.e., a thymine nucleotide analog having an allyl functionality).

The other primers (PA-PD) mentioned above include:

PA 5′→3′
(SEQ. ID. NO. 8)
GCTGGCACGTCCGAACGCTTCGTTAATCCGTTGAG
PB 5′→3′
(SEQ. ID. NO. 9)
CGTCGTCTGCCATGGCGCTTCGGTGGATATGAACT
PC 5′→3′
(SEQ. ID. NO. 10)
ACGGCCGCTAATATCAACGCGTCGAATCCGCAACT
PD 5′→3′
(SEQ. ID. NO. 11)
GCCGCGTTACGTTAGCCGGACTATTCGATGCAGC

While not shown in the example sequences for PA-PD, it is to be understood that any of these primers may include a cleavage site, such as uracil, 8-oxoguanine, allyl-T, etc. at any point in the strand.

Each of the primers disclosed herein may also include a polyT sequence at the 5′ end of the primer sequence. In some examples, the polyT region includes from 2 T bases to 20 T bases. As specific examples, the polyT region may include 3, 4, 5, 6, 7, or 10 T bases.

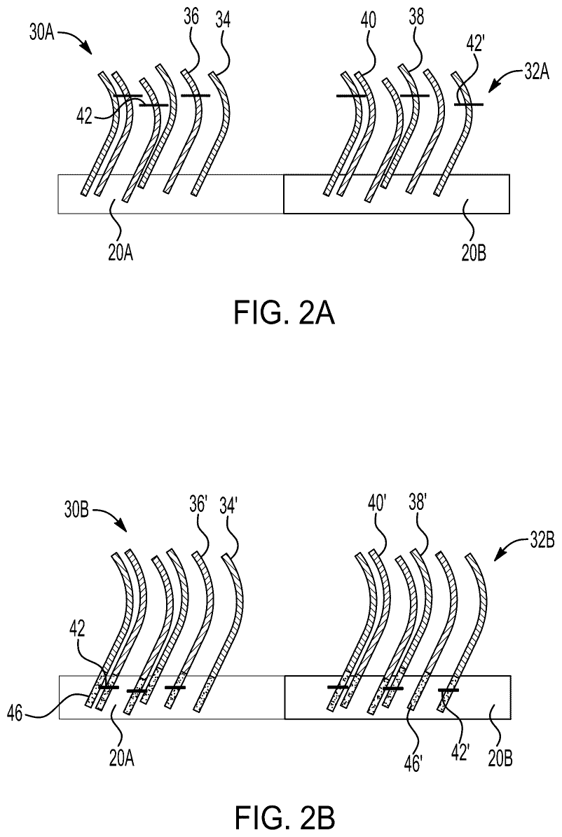

The 5′ end of each primer may also include a linker (e.g., 46, 46′ described in reference to FIG. 2B and FIG. 2D). Any linker that includes a terminal alkyne group or another suitable terminal functional group that can attach to the surface functional groups of the functionalized layer 20 or 20A, 20B may be used. In one example, the primers are terminated with hexynyl.

In any of the examples using the primer set 30′, the attachment of the primers 31, 33 to the functionalized layer 20 leaves a template-specific portion of the primers 31, 33 free to anneal to its cognate template and the 3′ hydroxyl group free for primer extension.

Turning now to the primer sets 30, 32, these primer sets are related in that one set includes an un-cleavable first primer and a cleavable second primer, and the other set includes a cleavable first primer and an un-cleavable second primer. The primer sets 30, 32 allow a single template strand to be amplified and clustered across both primer sets 30, 32, and also enable the generation of forward and reverse strands on adjacent functionalized layer 20A, 20B due to the cleavage groups being present on the opposite primers of the sets 30, 32. Examples of these primer sets 30, 32 will be discussed in reference to FIG. 2A through FIG. 2D.

FIG. 2A through FIG. 2D depict different configurations of the primer sets 30A, 32A, 30B, 32B, 30C, 32C, and 30D, 32D attached to the functionalized layers 20A, 20B.

Each of the first primer sets 30A, 30B, 30C, and 30D includes an un-cleavable first primer 34 or 34′ and a cleavable second primer 36 or 36′; and each of the second primer sets 32A, 32B, 32C, and 32D includes a cleavable first primer 38 or 38′ and an un-cleavable second primer 40 or 40′.

The un-cleavable first primer 34 or 34′ and the cleavable second primer 36 or 36′ are oligonucleotide pairs, e.g., where the un-cleavable first primer 34 or 34′ is a forward amplification primer and the cleavable second primer 36 or 36′ is a reverse amplification primer or where the cleavable second primer 36 or 36′ is the forward amplification primer and the un-cleavable first primer 34 or 34′ is the reverse amplification primer. In each example of the first primer set 30A, 30B, 30C, and 30D, the cleavable second primer 36 or 36′ includes a cleavage site 42, while the un-cleavable first primer 34 or 34′ does not include a cleavage site 42.

The cleavable first primer 38 or 38′ and the un-cleavable second primer 40 or 40′ are also oligonucleotide pairs, e.g., where the cleavable first primer 38 or 38′ is a forward amplification primer and un-cleavable second primer 40 or 40′ is a reverse amplification primer or where the un-cleavable second primer 40 or 40′ is the forward amplification primer and the cleavable first primer 38 or 38′ is the reverse amplification primer. In each example of the second primer set 32A, 32B, 32C, and 32D, the cleavable first primer 38 or 38′ includes a cleavage site 42′ or 44, while the un-cleavable second primer 40 or 40′ does not include a cleavage site 42′ or 44.

It is to be understood that the un-cleavable first primer 34 or 34′ of the first primer set 30A, 30B, 30C, and 30D and the cleavable first primer 38 or 38′ of the second primer set 32A, 32B, 32C, and 32D have the same nucleotide sequence (e.g., both are forward amplification primers), except that the cleavable first primer 38 or 38′ includes the cleavage site 42′ or 44 integrated into the nucleotide sequence (shown in FIG. 2A and FIG. 2C) or into a linker 46′ attached to the nucleotide sequence (shown in FIG. 2B and FIG. 2D). Similarly, the cleavable second primer 36 or 36′ of the first primer set 30A, 30B, 30C, and 30D and the un-cleavable second primer 40 or 40′ of the second primer set 32A, 32B, 32C, and 32D have the same nucleotide sequence (e.g., both are reverse amplification primers), except that the cleavable second primer 36 or 36′ includes the cleavage site 42 integrated into the nucleotide sequence (as shown in FIG. 2A and FIG. 2C) or into a linker 46 attached to the nucleotide sequence (as shown in FIG. 2B and FIG. 2D).

It is to be understood that when the first primers 34 and 38 or 34′ and 38′ are forward amplification primers, the second primers 36 and 40 or 36′ and 40′ are reverse primers, and vice versa.

The un-cleavable primers 34, 40 or 34′, 40′ may be any primers with a universal sequence for capture and/or amplification purposes, such as the P5 or P15 and P7 primers or any combination of the PA, PD, PC, PD primers (e.g., PA and PB or PA and PD, etc.). In some examples, the P5 and P7 primers are un-cleavable primers 34, 40 or 34′, 40′ because they do not include a cleavage site 42, 42′, 44. For example, the sequences set forth herein for P5 and P7 do not include uracil, inosine, alkene-thymidine, or 8-oxoguanine. It is to be understood that any suitable universal sequence can be used as the un-cleavable primers 34, 40 or 34′, 40′.

Examples of cleavable primers 36, 38 or 36′, 38′ include the P5 and P7 primers or other universal sequence primers (e.g., the PA, PB, PC, PD primers) with the respective cleavage sites 42, 42′, 44 incorporated into the respective nucleic acid sequences (e.g., FIG. 2A and FIG. 2C), or into a linker 46′, 46 that attaches the cleavable primers 36, 38 or 36′, 38′ to the respective functionalized layers 20A, 20B (FIG. 2B and FIG. 2D). Examples of suitable cleavage sites 42, 42′, 44 include enzymatically cleavable nucleobases or chemically cleavable nucleobases, modified nucleobases, or linkers (e.g., between nucleobases), as described herein.

Each primer set 30A and 32A or 30B and 32B or 30C and 32C or 30D and 32D is attached to a respective functionalized layer 20A, 20B. As described herein, the functionalized layer 20A, 20B may include different functional groups that can selectively react with the respective primers 34, 36 or 34′, 36′ or 38, 40 or 38′, 40′, or may include the same functional groups and the respective primers 34, 36 or 34′, 36′ or 38, 40 or 38′, 40′ may be pre-grafted or sequentially attached as described in some of the methods.

While not shown in FIG. 2A through FIG. 2D, it is to be understood that one or both of the primer sets 30A, 30B, 30C, 30D or 32A, 32B, 32C or 32D may also include a PX primer for capturing a library template seeding molecule. As one example, PX may be included with the primer set 30A, 30B, 30C, 30D, but not with primer set 32A, 32B, 32C or 32D. As another example, PX may be included with the primer set 30A, 30B, 30C, 30D and with the primer set 32A, 32B, 32C or 32D. The density of the PX motifs should be relatively low in order to minimize polyclonality within each depression 12.

The PX capture primers may be:

PX 5′ → 3′
(SEQ. ID. NO. 12)
AGGAGGAGGAGGAGGAGGAGGAGG
cPX (PX′) 5′ → 3′
(SEQ. ID. NO. 13)
CCTCCTCCTCCTCCTCCTCCTCCT

FIG. 2A through FIG. 2D depict different configurations of the primer sets 30A, 32A, 30B, 32B, 30C, 32C, and 30D, 32D attached to the functionalized layers 20A, 20B. More specifically, FIG. 2A through FIG. 2D depict different configurations of the primers 34, 36 or 34′, 36′ and 38, 40 or 38′, 40′ that may be used.

In the example shown in FIG. 2A, the primers 34, 36 and 38, 40 of the primer sets 30A and 32A are directly attached to the functionalized layers 20A or 20B, for example, without a linker 46, 46′. The functionalized layer 20A may have surface functional groups that can immobilize the terminal groups at the 5′ end of the primers 34, 36. Similarly, the functionalized layer 20B may have surface functional groups that can immobilize the terminal groups at the 5′ end of the primers 38, 40. In one example, the immobilization chemistry between the functionalized layer 20A and the primers 34, 36, and the immobilization chemistry between the functionalized layer 20B and the primers 38, 40 may be different so that the primers 34, 36 or 38, 40 selectively attach to the desirable layer 20A or 20B. For example, the functionalized layer 20A may be an azido silane that can graft an alkyne terminated primer, and the functionalized layer 20B may be an alkyne functionalized silane that can graft an azide terminated primer. For another example, the functionalized layer 20A may be an amine functionalized silane that can graft an NHS-ester terminated primer, and the functionalized layer 20B may be maleimide silane that can graft a thiol terminated primer. In another example, the immobilization chemistry may be the same for layer 20A and layer 20B and the respective primers 34, 36 or 38, 40, and a patterning technique may be used to graft one primer set 30A, 32A at a time. In still another example, the materials applied to form the functionalized layers 20A, 20B may have the respective primers 34, 36 or 38, 40 pre-grafted thereto, and thus the immobilization chemistries may be the same or different.

In this example, immobilization may be by single point covalent or by a strong non-covalent attachment to the respective functionalized layer 20A, 20B at the 5′ end of the respective primers 34 and 36 or 38 and 40.

Examples of terminated primers that may be used include an alkyne terminated primer, a tetrazine terminated primer, an azido terminated primer, an amino terminated primer, an epoxy or glycidyl terminated primer, a thiophosphate terminated primer, a thiol terminated primer, an aldehyde terminated primer, a hydrazine terminated primer, a phosphoramidite terminated primer, a triazolinedione terminated primer, and a biotin-terminated primer. In some specific examples, a succinimidyl (NHS) ester terminated primer may be reacted with an amine at a surface of the functionalized layer 20A, 20B, an aldehyde terminated primer may be reacted with a hydrazine at a surface of the functionalized layer 20A, 20B, or an alkyne terminated primer may be reacted with an azide at a surface of the functionalized layer 20A, 20B, or an azide terminated primer may be reacted with an alkyne or DBCO (dibenzocyclooctyne) at a surface of the functionalized layer 20A, 20B, or an amino terminated primer may be reacted with an activated carboxylate group or NHS ester at a surface of the functionalized layer 20A, 20B, or a thiol terminated primer may be reacted with an alkylating reactant (e.g., iodoacetamine or maleimide) at a surface of the functionalized layer 20A, 20B, a phosphoramidite terminated primer may be reacted with a thioether at a surface of the functionalized layer 20A, 20B, or a biotin-modified primer may be reacted with streptavidin at a surface of the functionalized layer 20A, 20B. In another example using biotin and streptavidin, streptavidin may be added to attach a biotin-modified primer and a biotinylated functionalized layer 20A, 20B.

Also, in the example shown in FIG. 2A, the cleavage site 42, 42′ of each of the cleavable primers 36, 38 is incorporated into the sequence of the primer. In this example, the same type of cleavage site 42, 42′ is used in the cleavable primers 36, 38 of the respective primer sets 30A, 32A. As an example, the cleavage sites 42, 42′ are uracil bases, and the cleavable primers 36, 38 are P5U (SEQ. ID NO. 1) and P7U (e.g., SEQ. ID. NOS. 4-6 with uracil instead of 8-oxoguanine). In this example, the un-cleavable primer 34 of the oligonucleotide pair 34, 36 may be P7 (e.g., SEQ. ID. NO. 4-6 without 8-oxoguanine), and the un-cleavable primer 40 of the oligonucleotide pair 38, 40 may be P5 (e.g., SEQ. ID. NOS. 1-3 without uracil, inosine, or alkene-thymidine). Thus, in this example, the first primer set 30A includes P7, P5U and the second primer set 32A includes P5, P7U. The primer sets 30A, 32A have opposite linearization chemistries, which, after amplification, cluster generation, and linearization, allows forward template strands to be formed on one functionalized layer 20A or 20B and reverse strands to be formed on the other functionalized layer 20A or 20B.

In the example shown in FIG. 2B, the primers 34′, 36′ and 38′, 40′ of the primer sets 30B and 32B are attached to the functionalized layers 20A, 20B, for example, through linkers 46, 46′. The functionalized layer 20A may have surface functional groups that can immobilize the linker 46 at the 5′ end of the primers 34′, 36′. Similarly, the functionalized layer 20B may have surface functional groups that can immobilize the linker 46′ at the 5′ end of the primers 38′, 40′. In one example, the immobilization chemistry for the functionalized layer 20A and the linkers 46 and the immobilization chemistry for the functionalized layer 20B and the linkers 46′ may be different so that the primers 34′, 36′ or 38′, 40′ selectively graft to the desirable functionalized layer 20A or 20B. In another example, the immobilization chemistry may be the same for the functionalized layers 20A or 20B′ and the linkers 46, 46′, and any suitable technique disclosed herein may be used to graft one primer set 30B, 32B at a time. In still another example, the materials applied to form the functionalized layers 20A and 20B may have the respective primers 34′, 36′ and 38′, 40′ pre-grafted thereto, and thus the immobilization chemistries may be the same or different.

Examples of suitable linkers 46, 46′ may include nucleic acid linkers (e.g., 10 nucleotides or less) or non-nucleic acid linkers, such as a polyethylene glycol chain, an alkyl group or a carbon chain, an aliphatic linker with vicinal diols, a peptide linker, etc. An example of a nucleic acid linker is a polyT spacer, although other nucleotides can also be used. In one example, the spacer is a 6T to 10T spacer. The following are some examples of nucleotides including non-nucleic acid linkers (where B is the nucleobase and “oligo” is the primer):

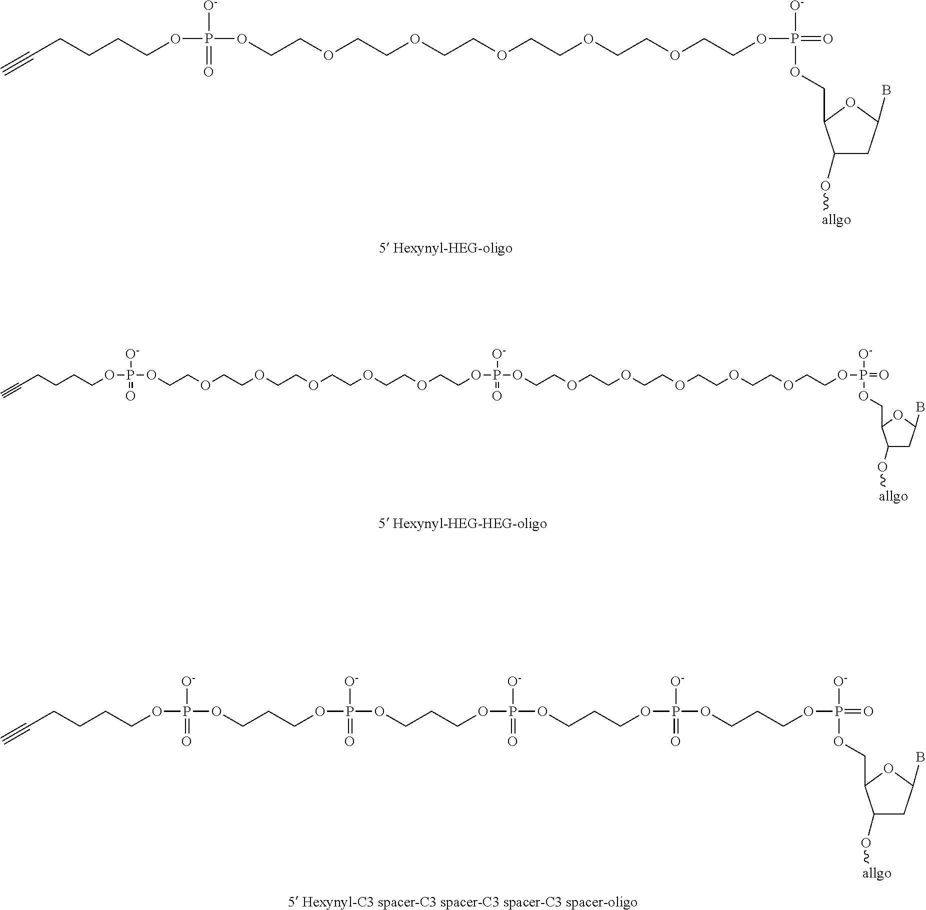

In the example shown in FIG. 2B, the primers 34′, 38′ have the same sequence (e.g., P5) and the same or different linker 46, 46′. The primer 34′ is un-cleavable (P5 without uracil, inosine, or alkene-thymidine), whereas the primer 38′ includes the cleavage site 42′ incorporated into the linker 46′. Also in this example, the primers 36′, 40′ have the same sequence (e.g., P7) and the same or different linker 46, 46′. The primer 40′ in un-cleavable (P7 without 8-oxoguanine), and the primer 36′ includes the cleavage site 42 incorporated into the linker 46. The same type of cleavage site 42, 42′ is used in the linker 46, 46′ of each of the cleavable primers 36′, 38′. As an example, the cleavage sites 42, 42′ may be uracil bases that are incorporated into nucleic acid linkers 46, 46′. The primer sets 30B, 32B have opposite linearization chemistries, which, after amplification, cluster generation, and linearization, allows forward template strands to be formed on one functionalized layer 20A or 20B and reverse strands to be formed on the other functionalized layer 20A or 20B.

The example shown in FIG. 2C is similar to the example shown in FIG. 2A, except that different types of cleavage sites 42, 44 are used in the cleavable primers 36, 38 of the respective primer sets 300, 32C. As examples, two different enzymatic cleavage sites may be used, two different chemical cleavage sites may be used, or one enzymatic cleavage site and one chemical cleavage site may be used. Examples of different cleavage sites 42, 44 that may be used in the respective cleavable primers 36, 38 include any combination of the following: vicinal diol, uracil, allyl ether, inosine, allyl-T, disulfide, restriction enzyme site, and 8-oxoguanine.

The example shown in FIG. 2D is similar to the example shown in FIG. 2B, except that different types of cleavage sites 42, 44 are used in the linkers 46, 46′ attached to the cleavable primers 36′, 38′ of the respective primer sets 30D, 32D. Examples of different cleavage sites 42, 44 that may be used in the respective linkers 46, 46′ attached to the cleavable primers 36′, 38′ include any combination of the following: vicinal diol, uracil, allyl ether, inosine, allyl-T, disulfide, restriction enzyme site, and 8-oxoguanine.

In any of the examples using the primer sets 30, 32, the attachment of the primers 34, 36 and 38, 40 or 34′, 36′ and 38′, 40′ to the functionalized layers 20A, 20B leaves a template-specific portion of the primers 34, 36 and 38, 40 or 34′, 36′ and 38′, 40′ free to anneal to its cognate template and the 3′ hydroxyl group free for primer extension.

Different methods that may be used to generate flow cells 10 are disclosed herein. The various methods will now be described.

### Method of Forming a Flow Cell Using a Sacrificial Layer

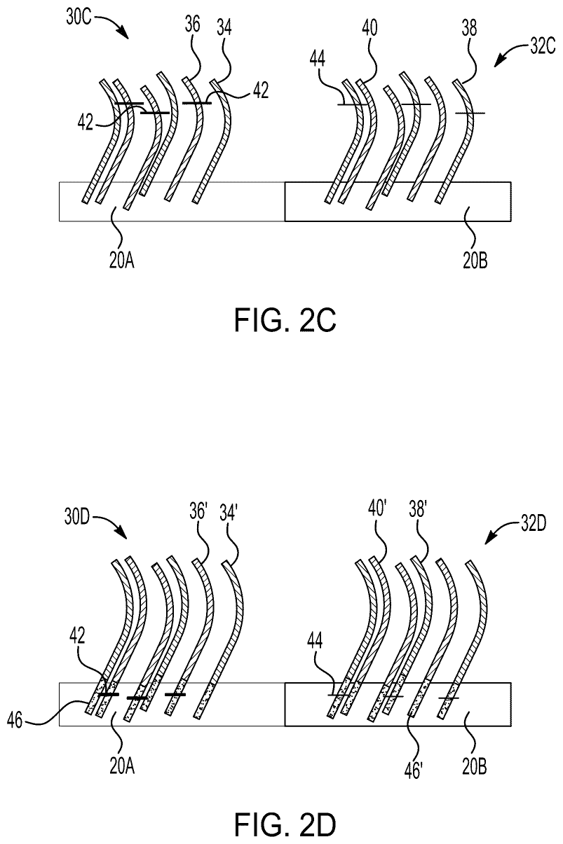

One method of forming a flow cell 10 is depicted in FIG. 3A through FIG. 3E. This example method includes applying a sacrificial layer 18 over interstitial regions 22 of a substrate 14′ or 15 including depressions 12 separated by the interstitial regions 22; depositing a functionalized layer 20 over the depressions 12 and over the sacrificial layer 18; and removing the sacrificial layer 18 from the interstitial regions 22, thereby removing the functionalized layer 20 that overlies the interstitial regions 22. While the examples of the method shown in FIG. 3A through FIG. 3E are depicted with the multi-layer substrate 15 including the base support 14 with the layer 16 thereon, it is to be understood that the method may be performed with the base support 14′ instead, where the depressions 12 are defined in the base support 14′ as described herein.

As shown in FIG. 3A, a depression 12 is defined in the layer 16. While a single depression 12 is shown in FIG. 3A through FIG. 3E, it is to be understood that the flow cell 10 may include a plurality of depressions 12, similar to the depressions 12 shown in FIG. 1B.

The depression 12 may be formed in the layer 16 of the multi-layer substrate 15 using any suitable technique, such as by etching, or by nanoimprint lithography (NIL), or by photolithography, etc. When a base support 14′ (of a single layer substrate) is used, the depression 12 may be formed in the base support 14′ using any suitable technique, such as photolithography, nanoimprint lithography (NIL), stamping techniques, laser-assisted direct imprinting (LADI) embossing techniques, molding techniques, etching/microetching techniques, etc.

One example of forming the depression 12 in the layer 16 is depicted in FIG. 3A. In this example, a working stamp 24 is pressed into the layer 16 while it is soft, which creates an imprint of the working stamp 24 features in the layer 16. The layer 16 may then be cured with the working stamp 24 in place. Curing may be accomplished by exposure to actinic radiation or heat. After curing, the working stamp 24 is released. This creates the depression 12 in the layer 16.

With the depression 12 formed in the layer 16 of the multi-layer substrate 15, this example method continues with the application of a sacrificial layer 18 over the depression 12 and over the interstitial regions 22.

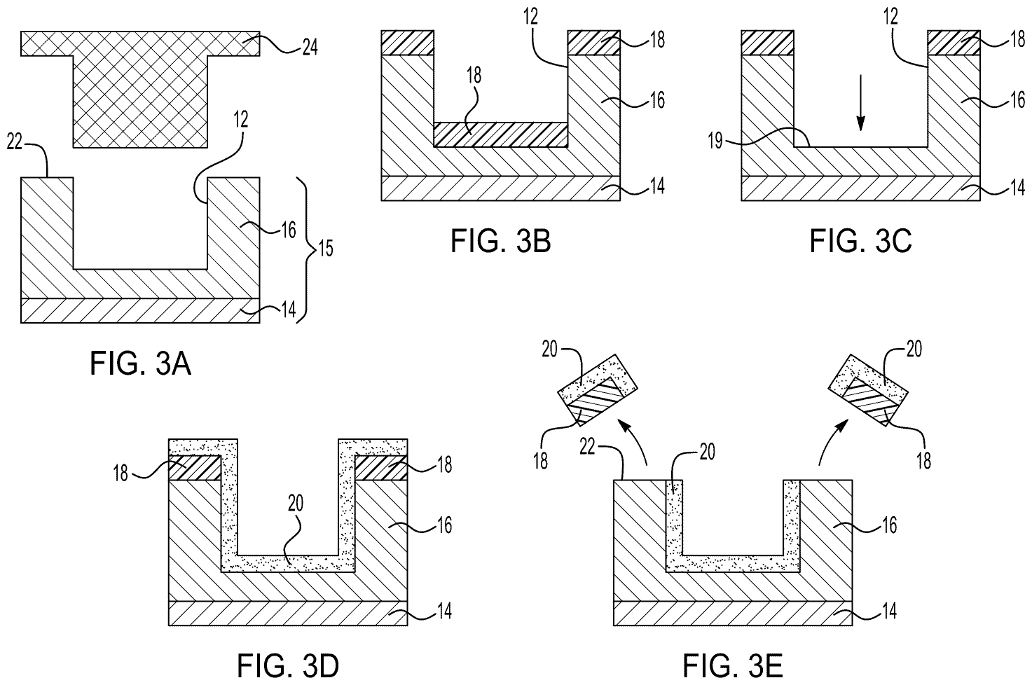

Examples of suitable materials for the sacrificial layer 18 include metals (e.g., aluminum, copper, titanium, gold, silver, etc.), photoresists, and nitrides (silicon, aluminum, tantalum, etc.). Further examples of the sacrificial layer 18 include semi-metals, such as silicon and germanium. In some examples, the semi-metal or metal may be at least substantially pure (<99% pure). In other examples, molecules or compounds of the listed elements may be used, as long as they provide the desired etch stop or other function in a particular method. For example, oxides of any of the listed semi-metals (e.g., silicon dioxide) or metals (e.g., aluminum oxide) may be used, alone or in combination with the listed semi-metal or metal. As another example, silicon nitride may be used, either alone or in combination with silicon. As further examples, aluminum nitride may be used (either alone or in combination with aluminum), or tantalum nitride may be used (either alone or in combination with tantalum). These materials may be deposited using any suitable technique disclosed herein. The deposition technique used may depend, in part, upon the material used for the sacrificial layer 18. It is to be understood that in some examples of the method (e.g., when a separate photoresist is used to apply the sacrificial layer 18 at desired areas, as described in reference to FIG. 4A through FIG. 4D), the sacrificial layer 18 may be a material other than a photoresist (e.g., a metal, a semi-metal, silicon nitride, etc.).

In some examples, selective deposition techniques (such as chemical vapor deposition (CVD) and variations thereof (e.g., low-pressure CVD or LPCVD)), atomic layer deposition (ALD), masking techniques, and/or etching may be used to apply the sacrificial layer 18 in the desirable areas. One of these examples involves: applying the sacrificial layer 18 over the depressions 12 and the interstitial regions 22, and etching the sacrificial layer 18 from the depressions 12, whereby the sacrificial layer 18 remains on the interstitial regions 22. This example is depicted in FIG. 3B and FIG. 3C, which will now be described.

As shown in FIG. 3B, the sacrificial layer 18 is applied within the depression 12 and over the interstitial regions 22. The sacrificial layer 18 may be applied so that it covers a bottom surface of the depression 12 and the interstitial regions 22 (as shown in FIG. 3B). While not shown in FIG. 3B, it is to be understood that the sacrificial layer 18 may conformally coat the layer 16 (and thus cover at least some sidewalls of the depression 12), or fill the depression 12.

As shown in FIG. 3C, portions of the sacrificial layer 18 within the depression 12 (and not over the interstitial regions 22) may then be etched (represented by the arrow in FIG. 3C). Any suitable etching technique may be used that can selectively remove portions of the sacrificial layer 18 from within the depression 12, while leaving portions of the sacrificial layer 18 on the interstitial regions 22 intact. The etching technique used may depend, in part, upon the material used for the sacrificial layer 18. The layer 16 of the multi-layer substrate 15 (or the base support 14′ of the single layer substrate) may function as an etch stop to sacrificial layer 18 etching, e.g., when the layer 16 of the multi-layer substrate has a different etch rate than the sacrificial layer 18. As shown in FIG. 3C, removal of the sacrificial layer 18 from within the depression 12 exposes a surface 19 of the depression 12, where the functionalized layer 20 is to be applied. It is to be understood that this etching step will also remove any of the sacrificial layer 18 from the sidewalls of the depression 12.

As examples, a reactive ion etch (e.g., with 10% CF₄ and 90% O₂) may be used that etches the sacrificial layer 18 at a rate of about 17 nm/min. In another example, a 100% O₂ plasma etch may be used that etches the sacrificial layer 18 at a rate of about 98 nm/min. Other suitable sacrificial layer 18 etchants include CF4/O₂/N₂, CHF3/O₂, and CHF3/CO₂. As still other specific examples, a CHF₃ and O₂ and Ar reactive ion etch may be used for a silicon dioxide sacrificial layer 18 or SF₆ and O₂ or CF₄ and O₂ or CF₄ may be used for a silicon nitride sacrificial layer.

In other examples, a photoresist that is resistant to etching may be applied and developed (as described herein) prior to etching. The photoresist may be any negative or positive photoresist and may be exposed to light so that an insoluble portion of the photoresist remains over the sacrificial layer 18 at the interstitial regions 22, and so that a soluble portion of the photoresist is removed from over the sacrificial layer 18 in the depression 12. This creates a mask over the interstitial regions 22 during the etching process. In these examples, the sacrificial layer 18 within the depression 12 is removed during etching, but the sacrificial layer 18 covered by the photoresist (e.g., at the interstitial regions 22) remains intact. In these examples, etching may be performed using a dry etch process, or a wet etch process. Examples of materials and suitable wet etchants/etching conditions may include: an aluminum sacrificial layer can be removed in acidic or basic conditions, a copper sacrificial layer can be removed using FeCl₃, a copper, gold or silver sacrificial layer can be removed in an iodine and iodide solution, a titanium sacrificial layer can be removed using H₂O₂, a silicon sacrificial layer can be removed in basic (pH) conditions, a silicon dioxide sacrificial layer can be removed using a hydrofluoric acid (HF) etch, and a silicon nitride sacrificial layer can be removed using a phosphoric acid etch.

While FIG. 3C depicts an example where the sacrificial layer 18 is etched from the depressions 12, it is to be understood that when the sacrificial layer 18 is a photoresist, an alternative method may be used. In this method, the photoresist can be developed so that the insoluble portions are formed over the interstitial regions 22 and soluble portions are removed from the depression 12. In this example, the photoresist may be a negative or positive photoresist that is initially deposited across the layer 16, both in the depressions 12 and over the interstitial regions 22, and then developed in a manner that is suitable for the photoresist being used.

Examples of suitable negative photoresists that may be used as the sacrificial layer 18 or that may be used to cover the sacrificial layer 18 (as described above) include those in the NR® series of photoresists (available from Futurrex), or in the SU-8 Series of photoresists, or in the KMPR® Series of photoresists (the two latter of which are available from Kayaku Advanced Materials, Inc.), or in the UVN™ Series of photoresists (available from DuPont). When the negative photoresist sacrificial layer 18 is used, it is selectively exposed to certain wavelengths of light to form an insoluble negative photoresist over the interstitial regions 22, and is exposed to a developer to remove soluble portions (e.g., those portions that are not exposed to the certain wavelengths of light) from the depressions 12.

Examples of suitable positive photoresists that may be used as the sacrificial layer 18 or that may be used to cover the sacrificial layer 18 (as described above) include those in the MICROPOSIT® S1800 series or the AZ® 1500 series, both of which are available from Kayaku Advanced Materials, Inc. Another example of a suitable positive photoresist is SPR™-220 (from DuPont). When a positive photoresist is used, selective exposure to certain wavelengths of light forms a soluble region (e.g., which is at least 95% soluble in a developer) in the depressions 12, and the developer is used to remove the soluble regions. Those portions of the positive photoresist overlying the interstitial regions 22 are not exposed to light, and will become insoluble in the developer. The insoluble positive photoresist thus remains over the interstitial regions 22.

The soluble portions are removed with a suitable developer so that the depressions 12 are exposed. Examples of suitable developers for the negative photoresist include aqueous-alkaline solutions, such as diluted sodium hydroxide, diluted potassium hydroxide, or an aqueous solution of the metal ion free organic TMAH (tetramethylammonium hydroxide). Examples of suitable developers for the positive photoresist include aqueous-alkaline solutions, such as diluted sodium hydroxide, diluted potassium hydroxide, or an aqueous solution of the metal ion free organic TMAH (tetramethylammonium hydroxide).

While some example methods of applying the sacrificial layer 18 to the interstitial regions 22 have been described, other examples may be used that involve photolithography and/or lift-off techniques. One of these examples, which is depicted in FIG. 4A through FIG. 4D, involves: generating an insoluble photoresist 48″ in the depressions 12, whereby the interstitial regions 22 are exposed, depositing the sacrificial layer 18 over the insoluble photoresist 48″ and the interstitial regions 22, and removing the insoluble photoresist 48″ and the sacrificial layer 18 thereon.

As shown in FIG. 4A, a photoresist 48 may be applied over the depression 12 and over the interstitial regions 22. Though the example shown in FIG. 4A through FIG. 4D utilizes a negative photoresist 48, the photoresist 48 may be a negative or positive photoresist 48. Any of the example negative or positive photoresists set forth herein may be used, and suitable light exposure may be performed in order to form the insoluble photoresist 48″ within the depressions 12.

As shown in FIG. 4B, the photoresist 48 may then be developed to define a pattern where soluble photoresist 48′ is removed from the interstitial regions 22, while leaving the insoluble photoresist 48″ in the depression 12 intact.

As shown in FIG. 4C, the sacrificial layer 18 may then be applied over the insoluble photoresist 48″ and over the interstitial regions 22 (e.g., where the soluble photoresist 48′ has been removed). As described, the sacrificial layer 18 may be a material other than a photoresist, such as a metal, a semi-metal, silicon nitride, etc., and these materials may be deposited using any suitable technique disclosed herein.

Following the application of the sacrificial layer 18, the insoluble photoresist 48″ (and the sacrificial layer 18 applied thereon) is then removed from the structure of FIG. 4C, which exposes the surface 19 of the depression 12. This is depicted in FIG. 4D. Suitable removers for the insoluble negative (or positive) photoresist 48″ include dimethylsulfoxide (DMSO) using sonication, acetone, and an NMP (N-methyl-2-pyrrolidone) based stripper. Another example of a remover for an insoluble positive photoresist is a propylene glycol monomethyl ether acetate wash.

Returning now to FIG. 3D, following the application of the sacrificial layer 18 over the interstitial regions 22 (and the exposure of the surface 19 of the depression 12), the method continues with the application of the functionalized layer 20. The functionalized layer 20 may be any of the examples set forth herein, and may be applied over the surface 19 of the depression 12 and over the sacrificial layer 18 (e.g., on the interstitial regions 22) using any of the deposition techniques set forth herein. In some examples, the functionalized layer 20 is also applied over at least some sidewalls of the depression 12. The attachment of the functionalized layer 20 to the layer 16 may be through covalent bonding. In some instances, depending on the materials used for the layer 16, the layer 16 may first be activated, e.g., through silanization or plasma ashing.

Any remaining portions of the sacrificial layer 18 (e.g., the portions on the interstitial regions 22) and the functionalized layer 20 that has been applied thereon are then removed via a lift-off process. This is depicted in FIG. 3E. The lift-off process may involve an organic solvent that is capable of dissolving or otherwise lifting off the sacrificial layer 18 without deleteriously affecting the functionalized layer 20 that is attached to the layer 16. As examples, an aluminum sacrificial layer 18 (and the functionalized layer 20 thereon) may be lifted-off using AZ® 400K (available from Microchemicals GmbH), and a silicon nitride sacrificial layer 18 (and the functionalized layer 20 thereon) may be lifted-off using KOH, AZ® 400K, citric acid, tartaric acid, HELLMANEX® (an alkaline cleaning concentrate available from Hellma) and the like. The sacrificial layer 18 is soluble (at least 99% soluble) in the solvent used in the lift-off process. The lift-off process removes i) at least 99% of the sacrificial layer 18 and ii) the functionalized layer 20 positioned thereon. The lift-off process does not remove the portion of the functionalized layer 20 that overlies (and is attached to) the layer 16 in the depression 12.

As shown in FIG. 3E, removal of the remaining portions of the sacrificial layer 18 (e.g., the portions over the interstitial regions 22) and the functionalized layer 20 thereon exposes the interstitial regions 22.

While not shown, the method shown in FIG. 3A through FIG. 3E also includes attaching a primer set 30′ to the functionalized layer 20. In some examples, the method further includes pre-grafting the primer set 30′, including primers 31, 33, to the functionalized layer 20. In these examples, the functionalized layer 20 is a pre-grafted polymeric hydrogel (i.e., the primers 31, 33 are attached before the polymeric hydrogel is applied). As such, in these examples, additional primer grafting is not performed.

In other examples, the primer set 30′, including primers 31, 33, is not pre-grafted to the functionalized layer 20. In these examples, the primers 31, 33 may be grafted after the functionalized layer 20 is applied (e.g., at FIG. 3D or at FIG. 3E).

When grafting is performed during the method, grafting may be accomplished using any suitable grafting techniques. As examples, grafting may be accomplished by flow through deposition (e.g., using a temporarily bound lid), dunk coating, spray coating, puddle dispensing, or by another suitable method. Each of these example techniques may utilize a primer solution or mixture, which may include the primer set 30′, water, a buffer, and a catalyst. With any of the grafting methods, the primers 31, 33 (of primer set 30′) react with reactive groups of the functionalized layer 20 and have no affinity for the layer 16 of the multi-layer substrate 15 (or the base support 14′ of the single layer substrate). As such, the interstitial regions 22 are free of the primers 31, 33.

While FIG. 3A through FIG. 3E illustrate the formation of a single depression 12 with the functionalized layer 20 therein, it is to be understood that an array of depressions 12 with the functionalized layer 20 therein may be formed, e.g., where each depression 12 is isolated from each other depression 12 by interstitial regions 22 of the layer 16 or the base support 14 of the single layer substrate (similar to the example shown in FIG. 1B).

Method of Forming a Flow Cell with Two Functionalized Layers Using Two Sacrificial Layers

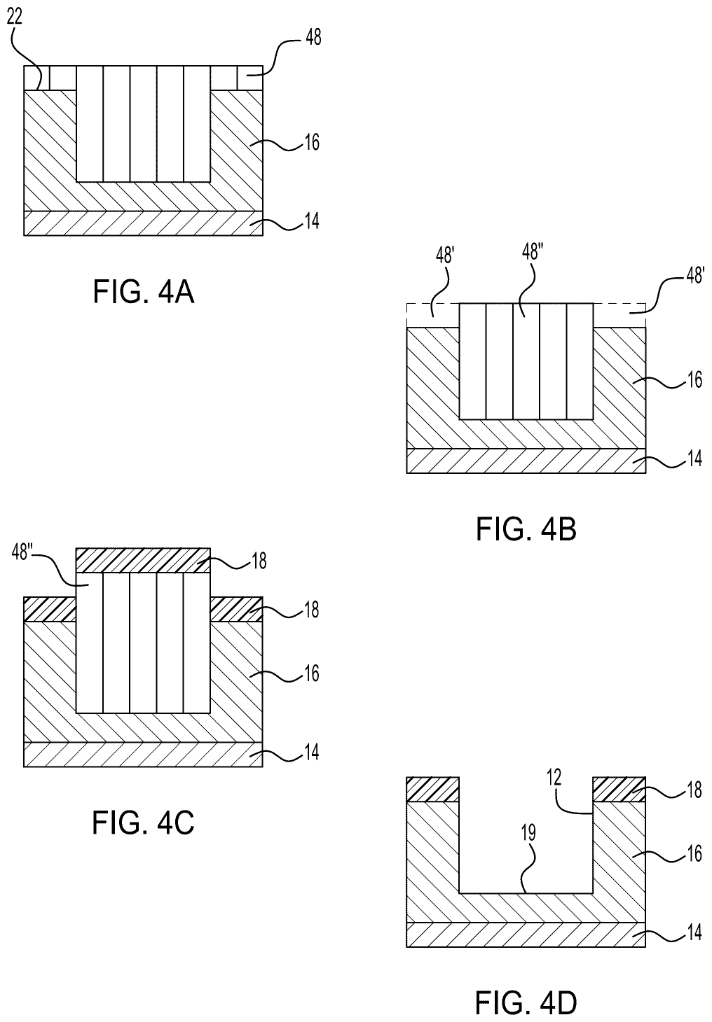

Referring now to FIG. 5A through FIG. 5G, another example of a method for making a flow cell 10 is depicted. This example involves applying a first sacrificial layer 18′ over interstitial regions 22 of a substrate 14′ or 15 including depressions 12 separated by the interstitial regions 22 (FIG. 5B); applying a second sacrificial layer 26 over the first sacrificial layer 18′ and over a first portion 74 of each of the depressions 12, whereby a second portion 72 of each of the depressions 12 remains exposed, wherein the second sacrificial layer 26 is orthogonal to the first sacrificial layer 18′ (FIG. 5C); applying a first functionalized layer 20A over the second sacrificial layer 26 and over the second portion 72 of each of the depressions 12 (FIG. 5D); removing the second sacrificial layer 26 and the first functionalized layer 20A applied thereon, thereby exposing the first portion 74 of each of the depressions 12 (FIG. 5E); applying a second functionalized layer 20B over the first portion 74 of each of the depressions 12 and over the first sacrificial layer 26 (FIG. 5F), and removing the first sacrificial layer 18′ and the second functionalized layer 20B applied thereon (FIG. 5G).

While the examples of the method shown in FIG. 5A through FIG. 5G are depicted with the multi-layer substrate 15 including the base support 14 with the layer 16 thereon, it is to be understood that the method may be performed with the base support 14′ instead, where the depressions 12 are defined in the base support 14′ as described herein.

As shown in FIG. 5A, a depression 12 is defined in the layer 16 of the multi-layer substrate 15. While a single depression 12 is shown in FIG. 5A through FIG. 5G, it is to be understood that the flow cell may include a plurality of depressions 12, similar to that shown in FIG. 1C.

The depression 12 may be formed in the layer 16 of the multi-layer substrate 15 using any suitable technique described herein, such as nanoimprint lithography (NIL) or photolithography, etc. While not shown in FIG. 5A through FIG. 5G, when a base support 14′ (of a single layer substrate) is used, the depression 12 may be formed in the base support 14′ using any suitable technique described herein, such as photolithography, nanoimprint lithography (NIL), stamping techniques, laser-assisted direct imprinting (LADI) embossing techniques, molding techniques, microetching techniques, etc.

With the depression 12 formed in the layer 16 of the multi-layer substrate 15, this example method continues with the application of each of the first sacrificial layer 18′ and the second sacrificial layer 26. Any example of the sacrificial layer 18 disclosed herein may be used for the first sacrificial layer 18′ and for the second sacrificial layer 26, as long the first sacrificial layer 18′ has a slower etch rate than the second sacrificial layer 26 in a particular etchant. A specific example of the sacrificial layers 18′, 26 that can be used together include aluminum (as layer 18′) and silicon nitride (as layer 26). Another example of sacrificial layers 18′, 26 that can be used together include two silicon nitride sacrificial layers 18′, 26 with different stoichiometry and different etch rates. The stoichiometry of the sacrificial layers 18′, 26 may be controlled during deposition of the sacrificial layers 18′, 26.

Different methods of depositing the first sacrificial layer 18′ and the second sacrificial layer 26 and generating the structure of FIG. 5C will now be described.

In one example, applying the first sacrificial layer 18′ over the interstitial regions 22 involves: depositing the first sacrificial layer 18′ over the substrate 15 and dry etching the first sacrificial layer 18′ from the depressions 12, whereby the first sacrificial layer 18′ remains on the interstitial regions 22. This is similar to the processes depicted in FIG. 3B and FIG. 3C, except that the first sacrificial layer 18′ is used instead of the sacrificial layer 18. Any suitable sacrificial layer 18 disclosed herein may be used for the first sacrificial layer 18′.

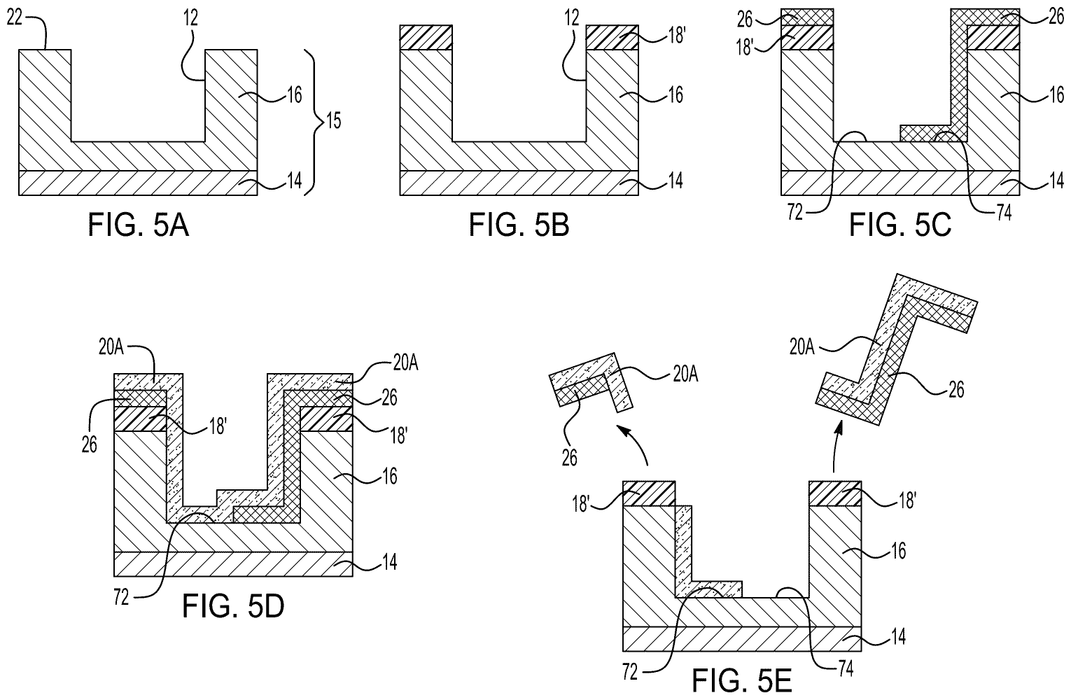

This example continues with the application of the second sacrificial layer 26. This is depicted in FIG. 6A through FIG. 6D. In this example, applying the second sacrificial layer 26 involves: applying a photoresist 48 over the substrate 15 and over the first sacrificial layer 18′ (as shown in FIG. 6A); developing the photoresist 48 to define a first pattern where soluble photoresist 48′ is removed from the first portion 74 of each of the depressions 12 and from the first sacrificial layer 18′, and a second pattern where insoluble photoresist 48″ remains over the second portion 72 of each of the depressions 12 (as shown in FIG. 6B); depositing the second sacrificial layer 26 over the insoluble photoresist 48″, the first portion 74 of each of the depressions 12, and the first sacrificial layer 18′ (as shown in FIG. 6C); and removing the insoluble photoresist 48″ and the second sacrificial layer 26 applied thereon (as shown in FIG. 6D). Removal of the insoluble photoresist 48″ and the second sacrificial layer 26 thereon exposes the second portion 72 of the depression 12 and generates the structure of FIG. 5C.

As shown in FIG. 6A, a photoresist 48 may be applied over the depression 12 and over the sacrificial layer 18′ positioned over the interstitial regions 22. Any of the example negative or positive photoresists set forth herein may be used, and suitable light exposure or non-exposure may be performed in order to form the insoluble photoresist 48″ in the portion 72 of the depression 12 and over the interstitial region 22 adjacent to the portion 72.

As shown in FIG. 6B, the photoresist 48 may then be developed. Development of the photoresist 48 defines a pattern where i) soluble photoresist 48′ is removed from the portion 74 of the depression 12 and from over the interstitial region 22 adjacent to the portion 74, and ii) insoluble photoresist 48″ remains in the portion 72 of the depression 12 and over the interstitial region 22 adjacent to the portion 72. Any of the developers set forth herein may be used to remove the soluble photoresist 48′, and will depend upon the photoresist that is used.

As shown in FIG. 6C, the second sacrificial layer 26 may then be applied over the insoluble photoresist 48″ and over the first sacrificial layer 18′ that is exposed (e.g., where soluble photoresist 48′ has been removed). As described, the sacrificial layer 26 may be deposited using any suitable technique disclosed herein.

Following the application of the second sacrificial layer 26, the insoluble photoresist 48″ (and the sacrificial layer 26 applied thereon) is then removed from the structure of FIG. 6C. As shown in FIG. 6D, this exposes the portion 72 of the depression 12 and the sacrificial layer 18′ positioned over the interstitial region 22 that is adjacent to the portion 72. Any suitable remover set forth herein may be used for the insoluble negative or positive photoresist 48″.

Another example of generating the structure of FIG. 5C utilizes the method shown in FIG. 4A through FIG. 4D to generate the first sacrificial layer 18′ and the method shown in FIG. 6A through FIG. 6D to generate the second sacrificial layer 26.

In this example, the formation of the first sacrificial layer 18′ involves: applying a first photoresist 48 over the substrate 15 (similar to FIG. 4A); developing the first photoresist 48 to define a first pattern where soluble first photoresist 48′ is removed from the interstitial regions 22, and a second pattern where insoluble first photoresist 48″ remains in each of the depressions 12 (similar to FIG. 4B); depositing the first sacrificial layer 18′ over the insoluble first photoresist 48″ and over the interstitial regions 22 (similar to FIG. 4C); and removing the insoluble first photoresist 48″ and the first sacrificial layer 18′ applied thereon, thereby exposing the depressions 12 (similar to FIG. 4D). Each of these steps may be performed as described in reference to FIG. 4A through FIG. 4D, except that the first sacrificial layer 18′ is used instead of the sacrificial layer 18.

This example method continues with the application of the second sacrificial layer 26. In this example, the formation of the second sacrificial layer 26 involves: applying a second photoresist 49 over the depressions 12 and over the first sacrificial layer 18′ (similar to FIG. 6A); developing the second photoresist 49 to define a third pattern where soluble second photoresist 49′ is removed from the first portion 74 of each of the depressions 12 and from the first sacrificial layer 18′, and a fourth pattern where insoluble second photoresist 49″ remains over the second portion 72 of each of the depressions 12 (similar to FIG. 6B); depositing the second sacrificial layer 26 over the insoluble second photoresist 49″, the first portion 74 of each of the depressions 12, and the first sacrificial layer 18′ (similar to FIG. 6C); and removing the insoluble second photoresist 49″ and the second sacrificial layer 26 applied thereon (similar to FIG. 6D). Each of these steps may be performed as described in FIG. 6A through FIG. 6D, except that a second photoresist 49 is used instead of a first photoresist 48, and soluble second photoresist 49′ is formed instead of soluble first photoresist 48′.

In this example method, the first photoresist 48 (used to apply the first sacrificial layer 18′) and/or the second photoresist 49 (used to apply the second sacrificial layer 26) used may be any of the negative and/or positive photoresists described herein. Any suitable developers and removers described herein may be used for the first photoresist 48 and/or the second photoresist 49.

In this example method, removal of the insoluble second photoresist 49″ and the second sacrificial layer 26 applied thereon exposes the portion 72 of the depression 12, while leaving the first sacrificial layer 18′ (remaining on the interstitial regions 22) intact. This generates the structure shown in FIG. 5C.

Following application of the first sacrificial layer 18′ and the second sacrificial layer 26 (as shown in FIG. 5C), the method then proceeds with the application of a first functionalized layer 20A over the second sacrificial layer 26 and over the exposed portion 72 of the depression 12, as shown in FIG. 5D. The first functionalized layer 20A may cover some sidewalls of the depression 12 (e.g., sidewalls that are not covered by the second sacrificial layer 26). The first functionalized layer 20A may be any of the examples set forth herein and may be applied using any of the deposition techniques set forth herein. In this example method, the layer 16 (including the portion 72 of the depression 12) may be activated to covalently attach the first functionalized layer 20A (as described hereinabove).

The second sacrificial layer 26 is then removed to expose the portion 74 of the depression 12 (e.g., the portion that had been covered by the second sacrificial layer 26). This is shown in FIG. 5E. Any suitable lift-off technique described herein may be used for the second sacrificial layer 26. It is to be understood that the functionalized layer 20A is covalently attached to the layer 16 of the multi-layer substrate 15 (or the base support 14′ of the single layer substrate) and thus is not removed from the layer 16 during lift-off of the second sacrificial layer 26. However, the functionalized layer 20A over the second sacrificial layer 26 will be removed.

It is to be further understood that in these examples, the material of the first sacrificial layer 18′ is different from the material of the second sacrificial layer 26, such that the first sacrificial layer 18′ and the second sacrificial layer 26 have orthogonal wet etch chemistries. In other words, the choice of wet etch reagents is such that the reagent used for etching the sacrificial layer 26 does not etch the sacrificial layer 18′ at all, or the reagent etches the sacrificial layer 18′ at a much lower rate in comparison to the etch rate of the sacrificial layer 26. As such, at least some of the first sacrificial layer 18′ remains intact over the interstitial regions 22 after the second sacrificial layer 26 is removed. In some instances, the first sacrificial layer 18′ is not affected by the removal of the second sacrificial layer 26, and in other instances, a minimal amount of the first sacrificial layer 18′ is removed during removal of the second sacrificial layer 26. The layer 16 (e.g., in the portion 74) may function as an etch stop to second sacrificial layer 26 etching, e.g., when the layer 16 has a different etch rate than the second sacrificial layer 26 or is not susceptible to the etchant/lift-off solvent that is used to remove the second sacrificial layer 26.

As shown in FIG. 5F, following removal of the second sacrificial layer 26, a second functionalized layer 20B may then be applied over the first sacrificial layer 18′ and over the exposed portion 74 of the depression 12 using any of the deposition techniques disclosed herein. The second functionalized layer 20B may be any of the examples set forth herein and may be deposited using any of the techniques disclosed herein. In this example, when the deposition of the functionalized layer 20B is performed under high ionic strength (e.g., in the presence of 10×PBS, NaCl, KCl, etc.), the second functionalized layer 20B does not deposit on or adhere to the first functionalized layer 20A. As such, the functionalized layer 20B does not contaminate the first functionalized layer 20A. In this example then, the functionalized layer 20B is deposited over the exposed portions (e.g., 74) of the layer 16 and over the first sacrificial layer 18′, but not over the first functionalized layer 20A.

The portion 74 may first have been activated to covalently attach the second functionalized layer 20B (as described herein).

Following the application of the functionalized layer 20B, the method proceeds with the removal of the first sacrificial layer 18′ from the interstitial regions 22. This is depicted in FIG. 5G. Any suitable lift-off technique described herein may be used for removal of the first sacrificial layer 18′. It is to be understood that the functionalized layers 20A, 20B are covalently attached to the layer 16 of the multi-layer substrate 15 and thus are not removed from the layer 16 during first sacrificial layer 18′ lift-off. However, the functionalized layer 20B over the first sacrificial layer 18′ will be removed. The layer 16 of the multi-layer substrate 15 may function as an etch stop to first sacrificial layer 18′ lift-off, e.g., when the layer 16 of the multi-layer substrate 15 has a different etch rate than the first sacrificial layer 18′ or is not susceptible to the etchant/lift-off solvent that is used to remove the first sacrificial layer 18′.

Removal of the first sacrificial layer 18′ (and the functionalized layer 20B thereon) exposes the interstitial regions 22 (shown in FIG. 5G).

While not shown, the method shown in FIG. 5A through FIG. 5G also includes attaching primer sets 30, 32 to respective functionalized layers 20A, 20B.

Some example methods include pre-grafting the primers 34, 36 or 34′, 36′ (not shown in FIG. 5A through FIG. 5G) to the first functionalized layer 20A. Similarly, the primers 38, 40 or 38′, 40′ (not shown in FIG. 5A through FIG. 5G) may be pre-grafted to the second functionalized layer 20B. In these examples, additional primer grafting is not performed.

In other examples, the primers 34, 36 or 34′, 36′ are not pre-grafted to the first functionalized layer 20A. In these examples, the primers 34, 36 or 34′, 36′ may be grafted after the functionalized layer 20A is applied (e.g., at FIG. 5D or FIG. 5E). In these examples, the primers 38, 40 or 38′, 40′ may be pre-grafted to the second functionalized layer 20B. Alternatively, in these examples, the primers 38, 40 or 38′, 40′ may not be pre-grafted to the second functionalized layer 20B. Rather, the primers 38, 40 or 38′, 40′ may be grafted after the second functionalized layer 20B is applied (e.g., at FIG. 5F or FIG. 5G), as long as i) the functionalized layer 20B has different functional groups (than first functionalized layer 20A) for attaching the primers 38, 40 or 38′, 40′ or ii) any unreacted functional groups of the first functionalized layer 20A have been quenched, e.g., using Staudinger reduction to amines or additional click reaction with a passive molecule such as hexynoic acid.

When grafting is performed during the method, grafting may be accomplished using any suitable grafting techniques, such as those disclosed herein. With any of the grafting methods, the primers 34, 36 or 34′, 36′ react with reactive groups of the functionalized layer 20A or the primers 38, 40 or 38′, 40′ react with reactive groups of the functionalized layer 20B, and have no affinity for the layer 16 of the multi-layer substrate 15 (or the base support 14′ of the single layer substrate).

While FIG. 5A through FIG. 5G illustrate the formation of a single depression 12 with functionalized layers 20A, 20B therein, it is to be understood that an array of depressions 12 with functionalized layers 20A, 20B therein may be formed, e.g., where each depression 12 is isolated from each other depression 12 by interstitial regions 22 of the layer 16 or the base support 14′ of the single layer substrate (similar to the example shown in FIG. 1C).

Method of Forming a Flow Cell with Two Functionalized Layers Using Two Different Sacrificial Layer Thicknesses

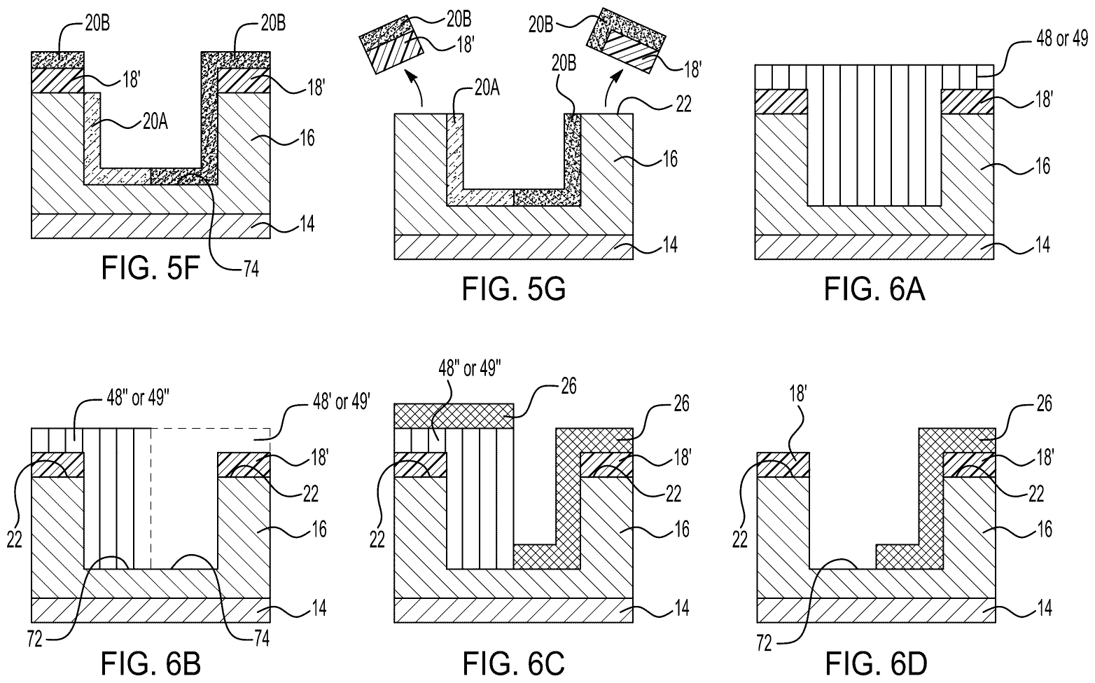

Referring now to FIG. 7A through FIG. 7F, another example of a method for making a flow cell 10 is depicted. This method involves applying a sacrificial layer 18″ over a first portion 74 of each of a plurality of depressions 12 defined in a substrate 15 and over interstitial regions 22 that separate the plurality of depressions 12, thereby forming a sacrificial layer 18″ having a first thickness T₁ over the first portions 74 and a second thickness T₂ over the interstitial regions 22, the second thickness T₂ being greater than the first thickness T₁, and whereby a second portion 72 of each of a plurality of depressions 12 remains exposed (FIG. 7B); applying a first functionalized layer 20A over the sacrificial layer 18″ and over the second portion 72 of each of the plurality of depressions 12 (FIG. 7C); removing at least some of the sacrificial layer 18″ to expose the first portion 74 of each of the plurality of depressions 12 and to reduce the second thickness T₂ (to a thickness of T₂′) (FIG. 7D); applying a second functionalized layer 20B over the first portion 74 of each of the plurality of depressions 12 and over the sacrificial layer 18″ having the reduced second thickness T₂′ (FIG. 7E); and removing the sacrificial layer 18″ having the reduced second thickness T₂′ and the second functionalized layer 20B applied thereon (FIG. 7F).

While the examples of the method shown in FIG. 7A through FIG. 7F are depicted with the multi-layer substrate 15 including the base support 14 with the layer 16 thereon, it is to be understood that the method may be performed with the base support 14′ instead, where the depressions 12 are defined in the base support 14′ as described herein.

As shown in FIG. 7A, a depression 12 is defined in the layer 16 of the multi-layer substrate 15. The depression 12 may be formed in the layer 16 using any suitable method described herein.

As shown in FIG. 7B, a sacrificial layer 18″ may then be applied over the interstitial regions 22 and over a portion 74 of the bottom of the depression 12, which leaves a portion 72 of the depression 12 exposed. The material of the sacrificial layer 18″ may be any suitable material described herein.

Some examples of applying the sacrificial layer 18″ involve sputtering or thermally evaporating a sacrificial layer 18″ material. For example, a metal material may be sputter coated or thermally evaporated on the surface of the layer 16 of the multi-layer substrate 15. During sputtering, the metal material is deposited at an angle (e.g., 45° or 60°) relative to the surface. This creates a shadow effect in the depression 12 where less or no metal material is deposited in an area of the depression 12 that is transverse to the incoming metal material. Thus, the substrate (e.g., the base support 14′ of the single layer substrate or the multi-layer substrate 15) is rotated throughout sputtering to introduce the metal material to particular area(s) of the depression 12. As the metal material continues to be applied to the interstitial regions 22 as the substrate is rotated, this process deposits more of the metal material on the interstitial regions 22 and less of the metal material in the depression 12 due, at least in part, to the shadow effect. The pressure may also be adjusted during sputtering. Low pressure (about 5 mTorr or less) renders sputtering more directional, which maximizes the shadow effect. A similar effect may be achieved with thermal evaporation (e.g., using low pressure), and thus this technique may be used instead of sputtering to create the sacrificial layer 18″. Thus, as a result of sputtering or thermal evaporation, a sacrificial layer 18″ having a first thickness T₁ is generated over a portion of the depression 12, while leaving a first portion 72′ of the depression 12 exposed, and a second thickness T₂ of the sacrificial layer 18″ is generated over the interstitial regions 22 (as shown in FIG. 7B). Sputtering or thermal evaporation may be controlled so that the first thickness T₁ is about 30 nm or less and is at least 10 nm thinner than the second thickness T₂.

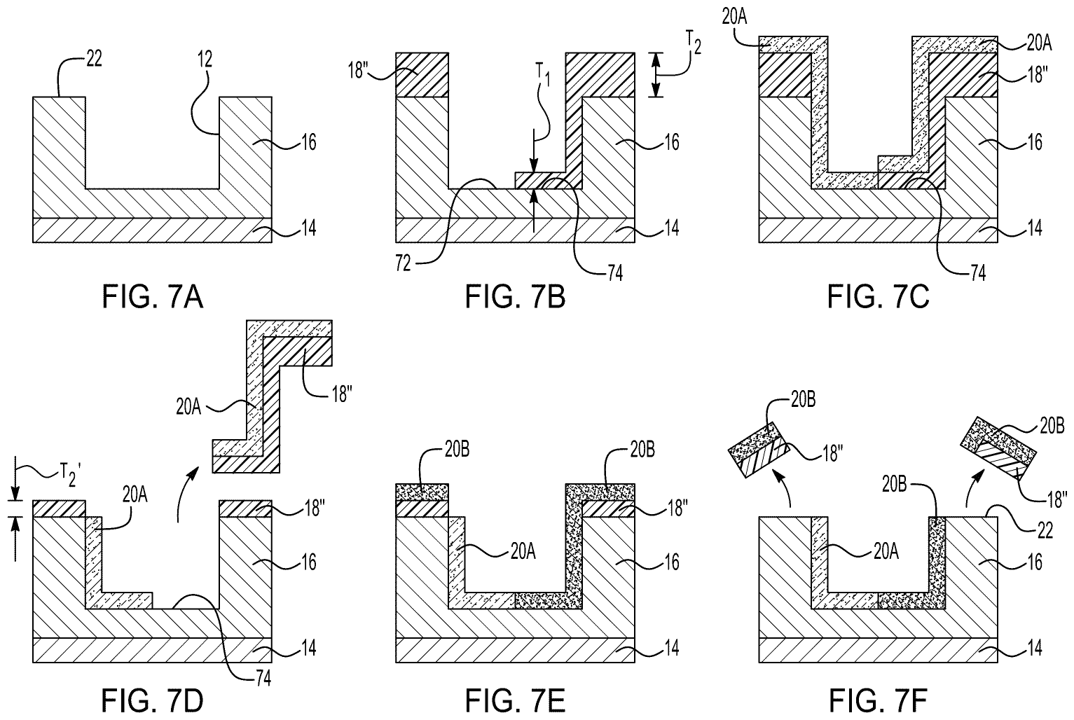

In other examples, photolithography and lift-off techniques are used to apply the sacrificial layer 18″ having the first thickness T₁ and the second thickness T₂ to generate the structure of FIG. 7B. One of these examples is depicted in FIG. 8A through FIG. 8H. In this example, applying the sacrificial layer 18″ involves: applying a first photoresist 48 over the substrate (as shown in FIG. 8A); developing the first photoresist 48 to define a first pattern where soluble first photoresist 48′ is removed from the first portion 74 of the depression 12 and from the interstitial regions 22, and a second pattern where insoluble first photoresist 48″ remains in the second portion 72 of the depression 12 (as shown in FIG. 8B); depositing the sacrificial layer 18″ over the insoluble first photoresist 48″, the interstitial regions 22, and the first portion 74 of each of the depressions 12 (as shown in FIG. 8C); removing the insoluble first photoresist 48″, thereby exposing the second portion 72 of the depressions 12 (as shown in FIG. 8D); applying a second photoresist 49 over the sacrificial layer 18″ and over the second portion 72 of the depressions 12 (as shown in FIG. 8E); developing the second photoresist 49 to form an insoluble second photoresist 49″, where soluble second photoresist 49′ is removed from the sacrificial layer 18″ overlying the interstitial regions 22 (FIG. 8F); depositing additional sacrificial layer 18″ material over the interstitial regions 22 and over the insoluble second photoresist 49″ (FIG. 8G); and removing the insoluble second photoresist 49″ (FIG. 8H). Removal of the insoluble second photoresist 49″ (and the sacrificial layer 18″ material thereon) exposes the portion 72 of the depression 12 and generates the structure of FIG. 7B.

As shown in FIG. 8A, the first photoresist 48 may be applied over the depression 12 and over the interstitial regions 22. Any of the example negative or positive photoresists set forth herein may be used, and suitable light exposure or non-exposure may be performed in order to form the insoluble photoresist 48″ in the portion 72 of the depression 12.

As shown in FIG. 8B, the first photoresist 48 may then be developed. Development of the first photoresist 48 defines a pattern where i) soluble photoresist 48′ is removed from the portion 74 of the depression 12 and from over the interstitial regions 22, and ii) insoluble photoresist 48″ remains in the portion 72 of the depression 12. Any of the developers set forth herein may be used to remove the soluble photoresist 48′, and will depend upon the photoresist that is used.

As shown in FIG. 8C, the sacrificial layer 18″ may then be applied over the insoluble first photoresist 48″ and over the exposed portions of the layer 16. As described, the sacrificial layer 18″ may be deposited using any suitable technique disclosed herein.

Following the application of the sacrificial layer 18″, the insoluble photoresist 48″ (and the sacrificial layer 18″ applied thereon) is then removed from the structure of FIG. 8C. As shown in FIG. 8D, this exposes the portion 72 of the depression 12. Any suitable remover set forth herein may be used for the insoluble first (negative or positive) photoresist 48″.

This example continues with the application of the second photoresist 49. As shown in FIG. 8E, the second photoresist 49 may be applied over the structure shown in FIG. 8D. Any of the example negative or positive photoresists set forth herein may be used, and suitable light exposure or non-exposure may be performed in order to form the insoluble second photoresist 49″ in the depression 12. In this example, the insoluble second photoresist 49″ overlies the portion 72 and a portion of the sacrificial layer 18″ that is present within the depression 12.

As shown in FIG. 8F, the second photoresist 49 may then be developed. Development of the second photoresist 49 defines a pattern where i) soluble second photoresist 49′ is removed from the sacrificial layer 18″ that overlies the interstitial regions 22, and ii) insoluble second photoresist 49″ remains in the depression 12. Any of the developers set forth herein may be used to remove the soluble second photoresist 49′, and will depend upon the photoresist that is used.

As shown in FIG. 8G, additional sacrificial layer 18″ may then be applied over the already present sacrificial layer 18″ and over the insoluble second photoresist 49″. The additional sacrificial layer 18″ may be deposited using any suitable technique disclosed herein. The additional sacrificial layer 18″ increases the thickness (from T₁ to T₂) of the sacrificial layer 18″ that is positioned on the interstitial regions 22. Due to the presence of the insoluble second photoresist 49″, the additional sacrificial layer 18″ is not applied within the depression 12.

Following the application of the additional sacrificial layer 18″, the insoluble second photoresist 49″ (and the sacrificial layer 18″ applied thereon) is then removed from the structure of FIG. 8G. As shown in FIG. 8H, this exposes the portion 72 of the depression 12 and the portion of the sacrificial layer 18″ having the first thickness (T₁). Any suitable remover set forth herein may be used for the insoluble second (negative or positive) photoresist 49″.

For the sacrificial layer 18″, it is to be understood that the first thickness T₁ may be about 30 nm or less and is at least 10 nm thinner than the second thickness T₂. In some examples, the first thickness T₁ is 20 nm or less (which provides desirable UV transmittance). As such, in some instances, T₁≤20≤T₂−10 nm. In one example, the second thickness T₂ is about 30 nm and the first thickness T₁ is at least 10 nm thinner (e.g., 20 nm or less, such as 8.5 nm, 15 nm, etc.). As other examples, T₁=30 nm and T₂=40 nm; T₁=5 nm and T₂=15 nm; T₁=10 nm and T₂=20 nm; and T₁=15 nm and T₂=25 nm.

Referring back to FIG. 7C, following the application of the sacrificial layer 18″, the method then proceeds with the application of a first functionalized layer 20A over the sacrificial layer 18″ (e.g., within the depression 12 and over the interstitial regions 22) and over the exposed second portion 72. Any example of the functionalized layer 20A may be used, and it may be deposited using any suitable technique. It is to be understood that the functionalized layer 20A covers the entire sacrificial layer 18″, including portions of the sacrificial layer 18″ with the thickness T₁ and portions with the thickness T₂. As explained hereinabove, the second portion 72 may have been activated to covalently attach the first functionalized layer 20A.

The entire sacrificial layer 18″ may then be exposed to a lift-off process. This process will remove the first functionalized layer 20A that is positioned on the sacrificial layer 18″, without removing the portion of the first functionalized layer 20A that is covalently attached at the second portion 72, due in part to the covalent bonding of the functionalized layer 20A to the layer 16. However, due to the differences in thickness T₁ and T₂, any portions of the sacrificial layer 18″ having the first thickness T₁ will be completely removed (along with any functional layer 20A thereon), while any portions of the sacrificial layer 18″ having the second thickness T₂ are reduced by the thickness of the first thickness T₁ to form a sacrificial layer 18″ having a reduced second thickness T₂′ on the interstitial regions 22 (without any functionalized layer 20A thereon). Any suitable etching process described herein may be used. This process exposes the first portion 74 of the depression 12.

In this example method, as shown at FIG. 7E, the second functionalized layer 20B is then applied over the depression 12 at the first portion 74 and on the sacrificial layer 18″ having the reduced second thickness T₂′ (that is positioned on the interstitial regions 22). As explained hereinabove, the first portion 74 may have been activated to covalently attach the second functionalized layer 20B. The second functionalized layer 20B may be any of the examples set forth herein and may be applied using any suitable deposition technique under high ionic strength conditions. As described herein, under the high ionic strength deposition conditions, the second functionalized layer 20B selectively attaches to the first portion 74 and not to the first functionalized layer 20A.

The sacrificial layer 18″ having the reduced second thickness T₂′ (and the functionalized layer 20B thereon) may be removed from the interstitial regions 22 using another lift-off process, as depicted in FIG. 7F. This leaves the functionalized layers 20A, 20B in the depression 12. The lift-off process used will depend upon the material of the sacrificial layer 18″.

Removal of the sacrificial layer 18″ having the reduced second thickness T₂′ and the functionalized layer 20B thereon exposes the interstitial regions 22, as depicted in FIG. 7F.

While not shown, the method described in reference to FIG. 7A through FIG. 7F also includes attaching a primer set 30, 32 to the functionalized layers 20A, 20B. In some examples, the primers 34, 36 or 34′, 36′ (not shown in FIG. 7A through FIG. 7F) may be pre-grafted to the functionalized layer 20A. Similarly, the primers 38, 40 or 38′, 40′ (not shown in FIG. 7A through FIG. 7F) may be pre-grafted to the functionalized layer 20B. In these examples, additional primer grafting is not performed.

In other examples, the primers 34, 36 or 34′, 36′ are not pre-grafted to the functionalized layer 20A. In these examples, the primers 34, 36 or 34′, 36′ may be grafted after the functionalized layer 20A is applied (e.g., at FIG. 7C or FIG. 7D). In these examples, the primers 38, 40 or 38′, 40′ may be pre-grafted to the second functionalized layer 20B. Alternatively, in these examples, the 38, 40 or 38′, 40′ may not be pre-grafted to the second functionalized layer 20B. Rather, the primers 38, 40 or 38′, 40′ may be grafted after the second functionalized layer 20B is applied (e.g., at FIG. 7E or at FIG. 7F), as long as i) the functionalized layer 20B has different functional groups (than functionalized layer 20A) for attaching the primers 38, 40 or 38′, 40′ or ii) any unreacted functional groups of the functionalized layer 20A have been quenched, e.g., using the Staudinger reduction to amines or additional click reaction with a passive molecule such as hexynoic acid.

When grafting is performed during the method, grafting may be accomplished using any of the grafting techniques described herein.

While FIG. 7A through FIG. 7F illustrate the formation of a single depression 12 with functionalized layers 20A, 20B therein, it is to be understood that an array of depressions 12 with functionalized layers 20A, 20B therein may be formed, e.g., where each depression 12 is isolated from each other depression 12 by interstitial regions 22 of the layer 16 or the base support 14′ of the single layer substrate (similar to the example shown in FIG. 1C).

To further illustrate the present disclosure, examples are given herein. It is to be understood that these examples are provided for illustrative purposes and are not to be construed as limiting the scope of the present disclosure.

### NON-LIMITING WORKING EXAMPLES

### Example 1

One of the methods described in FIG. 3A through FIG. 3E was used in this example. A silanized complementary metal-oxide-semiconductor silicon substrate having a tantalum oxide layer patterned with depressions was used. A photoresist was used as the sacrificial layer and was applied and developed such that it was present over the interstitial regions and removed from the depressions. PAZAM including TAMRA™ fluor 545 (a carboxylic acid of tetramethylrhodamine (TMR) from Invitrogen) as a fluorescent label was used as the hydrogel, and was deposited over the photoresist and in the depressions. The substrate was exposed to acetone and manual agitation for about 5 minutes to remove the photoresist and the PAZAM positioned thereon.

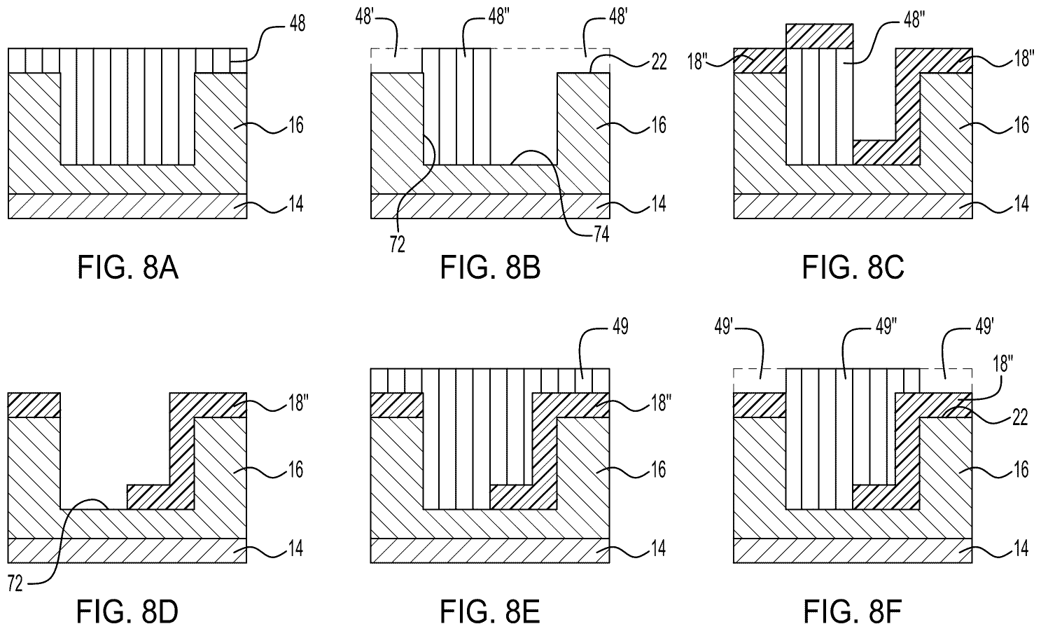

SEM (scanning electron microscope) images of the flow cell surface were taken before acetone exposure (FIG. 9A) and after acetone exposure (FIG. 9B). These results illustrated the successful removal of the photoresist sacrificial layer (and the overlying PAZAM) from the interstitial regions, while leaving the PAZAM within the depression intact.

### Example 2

In this example, a silanized complementary metal-oxide-semiconductor silicon substrate having a tantalum oxide layer patterned with depressions was used. Silicon nitride was used as the sacrificial layer. The silicon nitride was applied over the depressions and over the interstitial regions. A photoresist was applied over the silicon nitride at the interstitial regions. A dry etching process was performed using CF₄ to remove the silicon nitride from within the depressions, while leaving the silicon nitride on the interstitial regions (e.g., the silicon nitride covered by the photoresist) intact.

PAZAM including ATTO™ 488 (VMAT2 polyclonal antibody from Alomone Labs) as a fluorescent label was used as the hydrogel, and was deposited over the silicon nitride and in the depressions. The substrate was exposed to HELLMANEX® (alkaline cleaning concentrate from Hellma) 1% at 60° C. to remove the silicon nitride and the PAZAM positioned thereon.

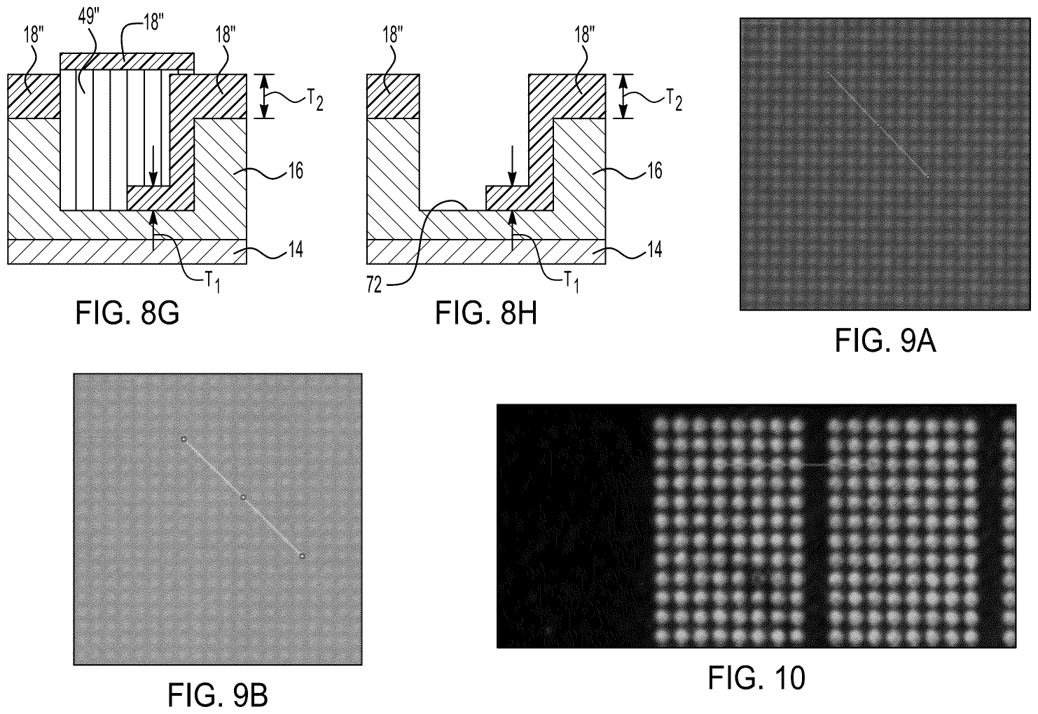

A confocal image of the substrate after silicon nitride removal was taken and is reproduced herein in black and white in FIG. 10. This image confirmed that the silicon nitride was an effective sacrificial layer for keeping the interstitial regions free of PAZAM.

### Additional Notes

It should be appreciated that all combinations of the foregoing concepts and additional concepts discussed in greater detail below (provided such concepts are not mutually inconsistent) are contemplated as being part of the inventive subject matter disclosed herein. In particular, all combinations of claimed subject matter appearing at the end of this disclosure are contemplated as being part of the inventive subject matter disclosed herein. It should also be appreciated that terminology explicitly employed herein that also may appear in any disclosure incorporated by reference should be accorded a meaning most consistent with the particular concepts disclosed herein.

Reference throughout the specification to “one example”, “another example”, “an example”, and so forth, means that a particular element (e.g., feature, structure, and/or characteristic) described in connection with the example is included in at least one example described herein, and may or may not be present in other examples. In addition, it is to be understood that the described elements for any example may be combined in any suitable manner in the various examples unless the context clearly dictates otherwise.

While several examples have been described in detail, it is to be understood that the disclosed examples may be modified. Therefore, the foregoing description is to be considered non-limiting.

What is claimed is:

1. A method, comprising:
applying a sacrificial layer over interstitial regions of a substrate including depressions separated by the interstitial regions;
depositing a functionalized layer over the depressions and over the sacrificial layer; and
removing the sacrificial layer from the interstitial regions, thereby removing the functionalized layer that overlies the interstitial regions.

2. The method as defined in claim 1, wherein applying the sacrificial layer involves:
depositing the sacrificial layer over the depressions and the interstitial regions; and
dry etching the sacrificial layer from the depressions, whereby the sacrificial layer remains on the interstitial regions.

3. The method as defined in claim 1, wherein applying the sacrificial layer involves:
generating an insoluble photoresist in the depressions, whereby the interstitial regions are exposed;
depositing the sacrificial layer over the insoluble photoresist and the interstitial regions; and
removing the insoluble photoresist and the sacrificial layer thereon.

4. The method as defined in claim 1, further comprising grafting a primer set to the functionalized layer over the depressions.

5. The method as defined in claim 1, wherein the functionalized layer is a pre-grafted polymeric hydrogel.

6. The method as defined in claim 1, further comprising forming the depressions in the substrate by etching or by nanoimprint lithography.

7. The method as defined in claim 1, wherein the sacrificial layer is a photoresist, a metal, a metal oxide, or a nitride.

8. A method, comprising:
applying a first sacrificial layer over interstitial regions of a substrate including depressions separated by the interstitial regions;
applying a second sacrificial layer over the first sacrificial layer and over a first portion of each of the depressions, whereby a second portion of each of the depressions remains exposed, wherein the second sacrificial layer is orthogonal to the first sacrificial layer;
applying a first functionalized layer over the second sacrificial layer and over the second portion of each of the depressions;
removing the second sacrificial layer and the first functionalized layer applied thereon, thereby exposing the first portion of each of the depressions;
applying a second functionalized layer over the first portion of each of the depressions and over the first sacrificial layer; and
removing the first sacrificial layer and the second functionalized layer applied thereon.

9. The method as defined in claim 8, further comprising attaching respective primer sets to the first and second functionalized layers.

10. The method as defined in claim 8, wherein applying the first sacrificial layer over the interstitial regions of the substrate involves:
depositing the first sacrificial layer over the substrate; and
dry etching the first sacrificial layer from the depressions, whereby the first sacrificial layer remains on the interstitial regions.

11. The method as defined in claim 10, wherein applying the second sacrificial layer involves:
applying a photoresist over the substrate and over the first sacrificial layer;
developing the photoresist to define a first pattern where soluble photoresist is removed from the first portion of each of the depressions and from the first sacrificial layer, and a second pattern where insoluble photoresist remains over the second portion of each of the depressions;
depositing the second sacrificial layer over the insoluble photoresist, the first portion of each of the depressions, and the first sacrificial layer; and
removing the insoluble photoresist and the second sacrificial layer applied thereon.

12. The method as defined in claim 8, wherein applying the first sacrificial layer over the interstitial regions of the substrate involves:
applying a photoresist over the substrate;
developing the photoresist to define a first pattern where soluble photoresist is removed from the interstitial regions, and a second pattern where insoluble photoresist remains in each of the depressions;
depositing the first sacrificial layer over the insoluble photoresist and over the interstitial regions; and
removing the insoluble photoresist and the first sacrificial layer applied thereon, thereby exposing the depressions.

13. The method as defined in claim 12, wherein applying the second sacrificial layer involves:
applying a second photoresist over the depressions and over the first sacrificial layer;
developing the second photoresist to define a third pattern where soluble second photoresist is removed from the first portion of each of the depressions and from the first sacrificial layer, and a fourth pattern where insoluble second photoresist remains over the second portion of each of the depressions;
depositing the second sacrificial layer over the insoluble second photoresist, the first portion of each of the depressions, and the first sacrificial layer; and
removing the insoluble second photoresist and the second sacrificial layer applied thereon.

14. The method as defined in claim 8, wherein the first sacrificial layer and the second sacrificial layer have orthogonal etch rates.

15. A method, comprising:
applying a sacrificial layer over a first portion of each of a plurality of depressions defined in a substrate and over interstitial regions that separate the plurality of depressions, thereby forming a sacrificial layer having a first thickness over the first portions and a second thickness over the interstitial regions, the second thickness being greater than the first thickness, and whereby a second portion of each of a plurality of depressions remains exposed;
applying a first functionalized layer over the sacrificial layer and over the second portion of each of the plurality of depressions;
removing at least some of the sacrificial layer to expose the first portion of each of the plurality of depressions and to reduce the second thickness;
applying a second functionalized layer over the first portion of each of the plurality of depressions and over the sacrificial layer having the reduced second thickness; and
removing the sacrificial layer having the reduced second thickness and the second functionalized layer applied thereon.

16. The method as defined in claim 15, wherein the first thickness is about 30 nm or less and is a least 10 nm thinner than the second thickness.

17. The method as defined in claim 15, further comprising attaching respective primer sets to the first and second functionalized layers.

18. The method as defined in claim 15, wherein applying the sacrificial layer involves sputtering or thermally evaporating the sacrificial layer.

19. The method as defined in claim 15, wherein applying the sacrificial layer involves:
applying a first photoresist over the substrate;
developing the first photoresist to define a first pattern where soluble first photoresist is removed from the first portion of each of the plurality of depressions and from the interstitial regions, and a second pattern where insoluble first photoresist remains in the second portion of each of the plurality of depressions;
depositing the sacrificial layer over the insoluble first photoresist, the interstitial regions, and the first portion of each of the plurality of depressions;
removing the insoluble first photoresist, thereby exposing the second portion of each of the plurality of depressions;
applying a second photoresist over the sacrificial layer and over the second portion of each of the plurality of depressions;
developing the second photoresist to form an insoluble second photoresist, where soluble second photoresist is removed from the sacrificial layer overlying the interstitial regions;
depositing additional sacrificial material over the sacrificial material overlying the interstitial regions and over the insoluble second photoresist; and
removing the insoluble second photoresist.
